(19) United States
(12) Patent Application Publication
(10) Pub. No.: US 2022/0093345 A1
(43) Pub. Date: Mar. 24, 2022

(54) TANDEM SOLAR MODULES AND METHODS OF MANUFACTURE THEREOF

(71) Applicant: Caelux Corporation, Pasadena, CA (US)

(72) Inventors: John Iannelli, San Marino, CA (US); Jiunn Benjamin Heng, Los Altos Hills, CA (US); Liam Sohngen, Pasadena, CA (US); Brian D. Hunt, La Cresenta, CA (US); Eric W. Wong, Los Angeles, CA (US); Jing-Shun Huang, Pasadena, CA (US); Chenyu Chou, Pasadena, CA (US)

(21) Appl. No.: 16/953,247

(22) Filed: Nov. 19, 2020

Related U.S. Application Data
(60) Provisional application No. 63/081,747, filed on Sep. 22, 2020.
(60) Provisional application No. 63/081,750, filed on Sep. 22, 2020.
(60) Provisional application No. 63/081,753, filed on Sep. 22, 2020.
(60) Provisional application No. 63/081,758, filed on Sep. 22, 2020.
(60) Provisional application No. 63/081,756, filed on Sep. 22, 2020.
(60) Provisional application No. 63/081,755, filed on Sep. 22, 2020.
(60) Provisional application No. 63/081,752, filed on Sep. 22, 2020.
(60) Provisional application No. 63/090,636, filed on Oct. 12, 2020.
(60) Provisional application No. 63/090,642, filed on Oct. 12, 2020.
(60) Provisional application No. 63/090,643, filed on Oct. 12, 2020.

(51) Int. Cl. H01G 9/20; H01L 27/30; H01L 27/28; H01L 51/42; H01L 51/44; H01G 9/00; H01L 51/00

(52) U.S. Cl. CPC H01G 9/2072; H01L 2251/308; H01L 27/286; H01L 51/4253; H01L 51/442; H01L 51/447; H01L 51/448; H01G 9/2009; H01G 9/2018; H01G 9/2027; H01G 9/2077; H01G 9/209; H01G 9/0036; H01L 51/0077; H01L 51/0047; H01L 51/004; H01L 27/302

(57) ABSTRACT

The present disclosure provides a tandem, 4-terminal, silicon-perovskite solar device. The device may comprise a silicon solar cell having a first band gap; a glass sheet covering the silicon solar cell, wherein the glass sheet comprises a top surface and a bottom surface; and a perovskite solar cell having a second band gap, wherein the perovskite solar cell is deposited on the bottom surface of the glass sheet.

### CROSS-REFERENCE

This application claims priority to U.S. Provisional Patent Application No. 63/081,747, filed on Sep. 22, 2020, U.S. Provisional Patent Application No. 63/081,750, filed on Sep. 22, 2020, U.S. Provisional Patent Application No. 63/081,753, filed on Sep. 22, 2020, U.S. Provisional Patent Application No. 63/081,758, filed on Sep. 22, 2020, U.S. Provisional Patent Application No. 63/081,756, filed on Sep. 22, 2020, U.S. Provisional Patent Application No. 63/081,755, filed on Sep. 22, 2020, and U.S. Provisional Patent Application No. 63/081,752, filed on Sep. 22, 2020, U.S. Provisional Patent Application No. 63/090,636, filed on Oct. 12, 2020, U.S. Provisional Patent Application No. 63/090,642, filed on Oct. 12, 2020, U.S. Provisional Patent Application No. 63/090,643, filed on Oct. 12, 2020, each of which is incorporated herein by reference in its entirety.

### BACKGROUND

Solar cells are electrical devices that convert light into electricity. Silicon solar cells may be capable of converting light with a wavelength greater than about 400 nanometers (“nm”) and less than about 1100 nm to electricity. However, the conversion efficiency of silicon solar cells may be increasingly poor as the wavelength of light decreases from 1100 nm. Additionally, silicon solar cells may be unable to convert wavelengths of light above about 1100 nm to electricity because such wavelengths of light lack the energy required to overcome the band gap of silicon.

A tandem solar cell may have two individual solar cells stacked on top of one another. The bottom cell may be a silicon solar cell, and the top cell may be made of a different material. The top cell may have a higher band gap than the silicon solar cell. Accordingly, the top cell may be capable of efficiently converting shorter wavelengths of light to electricity. The top cell may be transparent to longer wavelengths of light, which may allow the underlying silicon solar cell to absorb and convert such longer wavelengths of light to electricity.

Optical losses at the interface between the top cell and the bottom cell and recombination losses in any of the layers of the top cell or bottom cell may result in a lower efficiency cell. Additionally, tandem solar cells may be difficult to manufacture.

### SUMMARY

The present disclosure describes tandem silicon-perovskite solar modules and manufacturing methods thereof. A tandem silicon-perovskite solar module as described herein may have a bottom silicon solar cell and a top perovskite solar cell. The perovskite solar cell may have a higher bandgap than the silicon solar cell. For example, the perovskite solar cell may have a bandgap of about 1.7 electron volts (“eV”) and the silicon solar cell may have a bandgap of about 1.1 eV. Accordingly, the perovskite solar cell may be capable of efficiently converting shorter wavelengths of light to electricity. The perovskite solar cell may be transparent to longer wavelengths of light, which may allow the underlying silicon solar cell to absorb and convert such longer wavelengths of light to electricity. Together, the perovskite solar cell and the silicon solar cell may be capable of efficiently converting a wider spectrum of light to electricity than a single solar cell (i.e., there may be less thermalization loss in a tandem cell than in a single cell solar module resulting in a higher full spectrum efficiency).

The silicon solar cell may be a monocrystalline or multi-crystalline silicon solar cell. The silicon solar cell may be a component of a conventional solar panel. The solar panel may have a back sheet on which the silicon solar cell is disposed. An encapsulant may cover the top of the silicon solar cell to prevent it from being exposed to dust and moisture. The solar panel may also have a top glass sheet that provides additional protection to the silicon solar cell.

The perovskite solar cell may be deposited on the bottom surface of the top glass sheet. This may differ from the construction of conventional tandem solar modules in which a perovskite cell is merely disposed on top of a silicon wafer. Depositing the perovskite solar cell on the bottom surface of the top glass sheet may allow manufacturers to incorporate perovskite solar cells into their conventional silicon solar panels with no re-tooling or process changes. Instead, such manufacturers can merely substitute a conventional glass sheet with the perovskite glass sheet. This disclosure may refer to the perovskite glass sheet as “active glass.”

The perovskite solar cell may have a first transparent conducting oxide (“TCO”) layer deposited on the top glass sheet, a hole transport layer (“HTL”) deposited on the first TCO layer, a perovskite layer deposited on the HTL, an electron transport layer (“ETL”) deposited on the perovskite layer, and a second TCO layer deposited on the ETL. The first and second TCO layers may serve as terminals for the perovskite solar cell. The ETL and HTL may facilitate electron and hole transport, respectively, while inhibiting hole and electron transport, respectively. The perovskite layer can absorb light to generate charge carriers, which results in a voltage and current flow across the terminals of the perovskite solar cell.

The perovskite solar cell and the silicon solar cell may be electrically isolated from each other, and each cell may have its own terminals. That is, the tandem solar module may be a 4-terminal module. The perovskite solar cell and the silicon solar cell may be connected in series or parallel by connecting the terminals in the appropriate manner. In the case of a series connection, the perovskite solar cell and the silicon solar cell may be current-matched. In the case of a parallel connection, the perovskite solar cell and the silicon solar cell may be voltage-matched.

The present disclosure also describes methods for fabricating the active glass described above. An active glass may comprise a perovskite layer formed by applying the perovskite precursors individually, and subsequently annealing the precursors. A metallic lead layer can be deposited, followed by an inorganic halide layer (e.g., methylammonium iodide/formamidinium iodide), followed by a halide (e.g., iodine). By applying the various precursors in such a fashion, the same deposition equipment can be used for multiple layers, decreasing complexity and cost, and enabling high throughput manufacturing processes to be used. Additionally, the various ratios of the precursors can be tightly controlled, resulting in higher quality films. Also, a variety of different precursors for each layer can be deposited to improve film quality. For example, lead acetate can be applied on the lead layer to improve integration of the organic halides and halides into the lead layer. Similarly, different halides can be introduced to improve grain growth and other film properties. The perovskite precursors can be applied by a variety of techniques, including ultrasonic-spray on and physical vapor deposition. Ultrasonic spray-on, when combined with multiple ‘shower head’ type nozzles, may provide for even and controlled application of precursors, which in turn can generate high quality films substantially free of defects.

In one aspect, the present disclosure provides a device, comprising: a silicon solar cell having a first band gap; a glass sheet covering the silicon solar cell, wherein the glass sheet comprises a top surface and a bottom surface; and a perovskite solar cell having a second band gap, wherein the perovskite solar cell is deposited on the bottom surface of the glass sheet. In some embodiments, the silicon solar cell is electrically isolated from the perovskite solar cell. In some embodiments, the silicon solar cell comprises two terminals and the perovskite solar cell comprises two terminals. In some embodiments, the perovskite solar cell comprises a photoactive perovskite layer, wherein the photoactive perovskite layer comprises CH₃NH₃PbX₃ or H₂NCHNH₂PbX₃. In some embodiments, X comprises iodide, bromide, chloride, or a combination thereof. In some embodiments, the perovskite solar cell comprises a first transparent conductive oxide (TCO) layer and a second TCO layer. In some embodiments, the first TCO layer and the second TCO layer are terminals of the perovskite solar cell. In some embodiments, the first TCO layer and the second TCO layer comprise indium oxide. In some embodiments, the perovskite solar cell comprises an electron transport layer (ETL) comprising phenyl-C61-butyric acid methyl ester. In some embodiments, the perovskite solar cell comprises a hole transport layer (HTL) comprising nickel oxide. In some embodiments, the device further comprises a plurality of silicon solar cells including the silicon solar cell and a plurality of perovskite solar cells including the perovskite solar cell, wherein the plurality of perovskite solar cells is laser scribed in the top glass sheet so as to voltage-match or current-match the plurality of perovskite solar cells to the plurality of silicon solar cells. In some embodiments, the top glass sheet has a surface area that substantially corresponds to a surface area of a 60- or 72-cell solar panel. In some embodiments, the top surface of the top glass sheet comprises an anti-reflective coating. In some embodiments, the top surface of the top glass sheet comprises polydimethylsiloxane (PDMS). In some embodiments, the PDMS comprises 1:10 alumina PDMS, textured 1:50 alumina PDMS, or textured PDMS. In some embodiments, the bottom surface of the top glass sheet has a textured surface. In some embodiments, the device further comprises an encapsulant disposed between the silicon solar cell and the perovskite solar cell. In some embodiments, the encapsulant is selected from the group consisting of ethylene-vinyl-acetate (“EVA”), thermal plastic polyolefin (“TPO”), PDMS, silicone, and paraffin. In some embodiments, the silicon solar cell and the perovskite solar cell are connected electrically in parallel. In some embodiments, the silicon solar cell and the perovskite solar cell are connected electrically in series. In some embodiments, the second bandgap is between about 1.5 and 1.9 electron volts (eV). In some embodiments, the device has a power conversion efficiency of at least about 30%. In some embodiments, the silicon solar cell is selected from the group consisting of a monocrystalline solar cell, a polycrystalline solar cell, a passivated emitter rear contact (PERC) solar cell, an interdigitated back contact cell (IBC), and a heterojunction with intrinsic thin layer (HIT) solar cell.

In another aspect, the present disclosure provides a device comprising: a silicon solar cell having a first band gap; a perovskite solar cell having a second band gap, wherein the perovskite solar cell is disposed adjacent to the silicon cell, and wherein the device has a power conversion efficiency of at least about 30%. In some embodiments, the silicon solar cell is electrically isolated from the perovskite solar cell. In some embodiments, the silicon solar cell comprises two terminals and the perovskite solar cell comprises two terminals. In some embodiments, the perovskite solar cell comprises a photoactive perovskite layer, wherein the photoactive perovskite layer comprises CH₃NH₃PbX₃ or H₂NCHNH₂PbX₃. In some embodiments, X comprises iodide, bromide, chloride, or a combination thereof. In some embodiments, the perovskite solar cell comprises a first transparent conductive oxide (TCO) layer and a second TCO layer. In some embodiments, the first TCO layer and the second TCO layer are terminals of the perovskite solar cell. In some embodiments, the first TCO layer and the second TCO layer comprise indium oxide. In some embodiments, the perovskite solar cell comprises an electron transport layer (ETL) comprising phenyl-C61-butyric acid methyl ester. In some embodiments, the perovskite solar cell comprises a hole transport layer (HTL) comprising nickel oxide. In some embodiments, the device further comprises an encapsulant disposed between the silicon solar cell and the perovskite solar cell. In some embodiments, the encapsulant is selected from the group consisting of ethylene-vinyl-acetate (“EVA”), thermal plastic polyolefin (“TPO”), PDMS, silicone, and paraffin. In some embodiments, the silicon solar cell and the perovskite solar cell are connected electrically in parallel. In some embodiments, the silicon solar cell and the perovskite solar cell are connected electrically in series. In some embodiments, the second bandgap is between about 1.5 and 1.9 electron volts (eV). In some embodiments, the silicon solar cell is selected from the group consisting of a monocrystalline solar cell, a polycrystalline solar cell, a passivated emitter rear contact (PERC) solar cell, an interdigitated back contact cell (IBC), and a heterojunction with intrinsic thin layer (HIT) solar cell.

In another aspect, the present disclosure provides a method for forming a transparent conductive layer of a solar cell, comprising: (a) using a deposition energy of at most about 0.6 Watts per square centimeter (W/cm²), depositing a buffer layer of the transparent conductive layer on the solar cell; and (b) using a deposition energy of at most about 1 W/cm⁻², depositing a bulk layer of the transparent conductive layer on the buffer layer. In some embodiments, (a) and (b) comprise a physical vapor deposition process. In some embodiments, buffer layer is at least 5 nanometers thick. In some embodiments, the method further comprises, prior to (a), depositing a silver layer on the solar cell. In some embodiments, the silver layer is at most about 10 angstroms thick. In some embodiments, the method further comprises annealing the transparent conductive layer.

In another aspect, the present disclosure provides a method for forming a perovskite layer of a solar cell, comprising: (a) depositing a metallic lead (Pb) layer on a top glass of the solar cell via physical vapor deposition; (b) applying a methylammonium iodide (MAI) or formamidinium iodide (FAI) layer on the metallic Pb layer via ultrasonic spray-on; and (c) exposing the MAI or FAI layer to iodine gas by translating a dispensing unit across the MAI or FAI layer, wherein the dispensing unit comprises a plurality of nozzles configured to provide the iodine gas. In some embodiments, the method further comprises, prior to (b), applying Pb salts to metallic lead layer. In some embodiments, the lead salts comprise one or more salts selected from the group consisting of lead (II) acetate, lead (II) chloride, lead (II) bromide, and lead (II) iodide. In some embodiments, the MAI or FAI layer comprises a methylammonium chloride (MACl) additive. In some embodiments, the method further comprises applying a phenylethylammonium iodide (PEAI) solution to the MAI or FAI layer. In some embodiments, (a)-(c) are performed in a chamber that is not reactive to the iodine gas. In some embodiments, the chamber is made of glass. In some embodiments, the chamber is made of titanium. In some embodiments, the method further comprises (d) performing one or more annealing operations to form the perovskite layer from the metallic Pb layer, the MAI or FAI layer, and the iodine gas. In some embodiments, the plurality of nozzles comprises one or more shower head nozzles.

In another aspect, the present disclosure provides a method for forming a perovskite layer of a solar cell, comprising: (a) using an ultrasonic dispensing unit comprising a plurality of nozzles to apply a lead halide layer comprising lead iodide, lead bromide, and lead chloride on the solar cell; and (b) using the ultrasonic dispensing unit to apply a methylammonium halide layer on the lead halide layer. In some embodiments, the lead halide layer comprises more lead chloride by weight than lead bromide.

Other aspects of the present disclosure provide methods of fabricating and manufacturing the devices and components described above and elsewhere in this disclosure

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “Figure” and “FIG.” herein), of which:

FIG. 1 schematically illustrates a tandem, 4-terminal, silicon-perovskite solar cell, according to an embodiment;

FIG. 2 schematically illustrates the formation of a perovskite layer of a solar cell, according to an embodiment;

FIG. 3 is a flow chart of a fabrication process for forming a perovskite photovoltaic, according to an embodiment of the present disclosure;

FIG. 4 is a flowchart of operation 310 of FIG. 3, according to an embodiment;

FIG. 5 is a flowchart of operation 340 of FIG. 3, according to an embodiment;

FIG. 6 is a flow chart of operation 350 of FIG. 3, according to an embodiment;

FIG. 7 is a flow chart of operation 360 of FIG. 3, according to an embodiment;

FIG. 8 schematically illustrates a perovskite precursor deposition chamber, according to an embodiment;

FIG. 9 schematically illustrates a shower head design for a spray-on nozzle, according to an embodiment;

FIG. 10 schematically illustrates an integrated production flow for a perovskite photovoltaic, according to an embodiment;

FIG. 11 shows the transmission of various wavelengths of light through a perovskite solar cell, according to an embodiment;

FIG. 12 shows a computer system that is programmed or otherwise configured to implement methods provided herein; and

FIG. 13 is a flow chart of a fabrication process for forming a perovskite layer, according to an embodiment.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

Whenever the term “at least,” “greater than,” or “greater than or equal to” precedes the first numerical value in a series of two or more numerical values, the term “at least,” “greater than” or “greater than or equal to” applies to each of the numerical values in that series of numerical values. For example, greater than or equal to 1, 2, or 3 is equivalent to greater than or equal to 1, greater than or equal to 2, or greater than or equal to 3.

Whenever the term “no more than,” “less than,” or “less than or equal to” precedes the first numerical value in a series of two or more numerical values, the term “no more than,” “less than,” or “less than or equal to” applies to each of the numerical values in that series of numerical values. For example, less than or equal to 3, 2, or 1 is equivalent to less than or equal to 3, less than or equal to 2, or less than or equal to 1.

The term “solar cell,” as used herein, generally refers to a device that uses the photovoltaic effect to generate electricity from light.

The term “tandem,” as used herein, refers to a solar module with two solar cells that are stacked on top of one another.

The term “4-terminal,” as used herein, refers to a tandem solar module in which the top and bottom solar cells each have two accessible terminals.

The term “perovskite,” as used herein, generally refers to a material with a crystal structure similar to calcium titanium oxide and one that is suitable for use in perovskite solar cells. The general chemical forum for a perovskite material is ABX₃. Examples of perovskite materials include methylammonium lead trihalide (i.e., CH₃NH₃PbX₃, where X is a halogen ion such as iodide, bromide, or chloride) and formamidinium lead trihalide (i.e., H₂NCHNH₂PbX₃, where X is a halogen ion such as iodide, bromide, or chloride).

The term “monocrystalline silicon,” as used herein, generally refers to silicon with a crystal structure that is homogenous throughout the material. The orientation, lattice parameters, and electronic properties of monocrystalline silicon may be constant throughout the material. Monocrystalline silicon may be doped with phosphorus or boron, for example, to make the silicon n-type or p-type respectively.

The term “polycrystalline silicon,” as used herein, generally refers to silicon with an irregular grain structure.

The terms “passivated emitter rear contact (PERC) solar cell,” as used herein, generally refer to a solar cell with an extra dielectric layer on the rear-side of the solar cell. This dielectric layer may act to reflect unabsorbed light back to the solar cell for a second absorption attempt, and may additionally passivate the rear surface of the solar cell, increasing the solar cell's efficiency.

The terms “heterojunction with intrinsic thin layer solar cell (HIT) solar cell,” as used herein, generally refer to a solar cell that is composed of a monocrystalline silicon wafer surrounded by ultra-thin amorphous silicon layers. One amorphous silicon layer may be n-doped, while the other may be p-doped.

The terms “an interdigitated back contact cell (IBC),” as used herein, generally refer to a solar cell comprising two or more electrical contacts disposed on the back side of the solar cell (e.g., on the side opposite the incident light). The two or more electrical contacts can be disposed adjacent to alternatingly n- and p-doped regions of the solar cell. An IBC may comprise a high-quality absorber material configured to permit carrier migration over a long distance.

The terms “bandgap” and “band gap,” as used herein, generally refer to the energy difference between the top of the valence band and the bottom of the conduction band in a material.

The term “electron transport layer” (“ETL”), as used herein, generally refers to a layer of material that facilitates electron transport and inhibits hole transport in a solar cell. Electrons may be majority carriers in an ETL, while holes may be minority carriers. An ETL may be made of one or more n-type layers. The one or more n-type layers may include an n-type exciton blocking layer. The n-type exciton blocking layer may have a wider band gap than the photoactive layer of the solar cell (e.g., the perovskite layer) but a conduction band that is closely matched to the conduction band of the photoactive layer. This may allow electrons to easily pass from the photoactive layer to the ETL.

The n-type layer may be a metal oxide, a metal sulfide, a metal selenide, a metal telluride, amorphous silicon, an n-type group IV semiconductor (e.g., germanium), an n-type group III-V semiconductor (e.g., gallium arsenide), an n-type group II-VI semiconductor (e.g., cadmium selenide), an n-type group I-VII semiconductor (e.g., cuprous chloride), an n-type group IV-VI semiconductor (e.g., lead selenide), an n-type group V-VI semiconductor (e.g., bismuth telluride), or an n-type group II-V semiconductor (e.g., cadmium arsenide), any of which may be doped (e.g., with phosphorus, arsenic, or antimony) or undoped. The metal oxide may be an oxide of titanium, tin, zinc, niobium, tantalum, tungsten, indium, gallium, neodymium, palladium, cadmium, or an oxide of a mixture of two or more of such metals. The metal sulfide may be a sulfide of cadmium, tin, copper, zinc or a sulfide of a mixture of two or more of such metals. The metal selenide may be a selenide of cadmium, zinc, indium, gallium or a selenide of a mixture of two or more of such metals. The metal telluride may be a telluride of cadmium, zinc, cadmium or tin, or a telluride of a mixture of two or more of said metals. Other n-type materials may alternatively be employed, including organic and polymeric electron transporting materials, and electrolytes. Suitable examples include, but are not limited to, a fullerene or a fullerene derivative (e.g., phenyl-C61-butyric acid methyl ester) or an organic electron transporting material comprising perylene or a derivative thereof.

The term “hole transport layer” (“HTL”), as used herein, generally refers to a layer of material that facilitates hole transport and inhibits electron transport in a solar cell. Holes may be majority carriers in an HTL, while electronics may be minority carriers. An HTL may be made of one or more p-type layers. The one or more p-type layers may include a p-type exciton blocking layer. The p-type exciton blocking layer may have a valence band that is closely matched to the valence bad of the photoactive layer (e.g., the perovskite layer) of the solar cell. This may allow holes to easily pass from the photoactive layer to the HTL.

The p-type layer may be made of a molecular hole transporter, a polymeric hole transporter, or a copolymer hole transporter. For example, the p-type layer may be one or more of the following: nickel oxide, thiophenyl, phenelenyl, dithiazolyl, benzothiazolyl, diketopyrrolopyrrolyl, ethoxydithiophenyl, amino, triphenyl amino, carbozolyl, ethylene dioxythiophenyl, dioxythiophenyl, or fluorenyl. Additionally or alternatively, the p-type may comprise spiro-OMeTAD (2,2′,7,7′-tetrakis-(N,N-di-p-methoxyphenylamine)-9,9′-spirobifluorene)), P3HT (poly(3-hexylthiophene)), PCPDTBT (Poly[2,1,3-benzothiadiazole-4,7-diyl[4,4-bis(2-ethylhexyl)-4H-cyclopenta[2,1-b:3,4-b′]dithiophene-2,6-diyl]]), PVK (poly(N-vinylcarbazole)), poly(3-hexylthiophene), poly[N,N-diphenyl-4-methoxyphenylamine-4′,4″-diyl], sexithiophene, 9,10-bis(phenylethynyl)anthracene, 5,12-bis(phenylethynyl)naphthacene, diindenoperylene, 9,10-diphenylanthracene, PEDOT-TMA, PEDOT:PSS, perfluoropentacene, perylene, poly(pphenylene oxide), poly(p-phenylene sulfide), quinacridone, rubrene, 4-(dimethylamino)benzaldehyde diphenylhydrazone, 4-(dibenzylamino) benzaldehyde-N,Ndiphenylhydrazone or phthalocyanines.

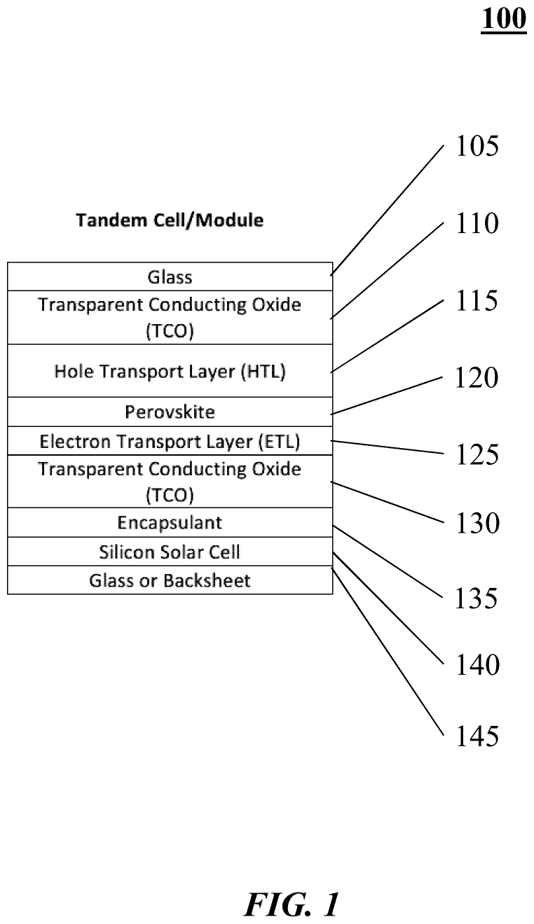

FIG. 1 schematically illustrates a tandem, 4-terminal, silicon-perovskite solar module 100, according to an embodiment of the present disclosure. The solar module 100 may have a top glass sheet 105, a first TCO layer 110, an HTL 115, a perovskite layer 120, an ETL 125, a second TCO layer 130, an encapsulant 135, a silicon solar cell 140, and a back sheet 145.

The top glass sheet 105 may protect underlying layers of the solar module 100 from dust and moisture. The top glass sheet 105, and the solar module 100 as a whole, may have a form factor that corresponds to a conventional silicon solar panel. For example, the top glass sheet 105 may have a form factor that corresponds to a 32-cell, 36-cell, 48-cell, 60-cell, 72-cell, 96-cell, or 144-cell silicon solar panel. The top glass sheet 105 may have a thickness of at least about 2.0 millimeters (mm), 2.5 mm, 3.0 mm, 3.5 mm, 4.0 mm, 4.5 mm, 5.0 mm, or more. The top glass sheet 105 may have a thickness of at most about 5.0 mm, 4.5 mm, 4.0 mm, 3.5 mm, 3.0 mm, 2.5 mm, 2.0 mm, or less. The top glass sheet 105 may be transparent so as to allow light to access the underlying solar cells. In some cases, the top surface of the top glass sheet 105 may be covered with polydimethylsiloxane (“PDMS”) (e.g., 1:10 alumina PDMS, textured 1:50 alumina PDMS, or textured PDMS), which may improve light trapping and refractive index matching. In some cases, the top surface of the top glass sheet 105 may be covered with an anti-reflective coating. In some cases, the bottom surface of the top glass sheet 105 may be textured in order to enable more light scattering back into the perovskite layer 120.

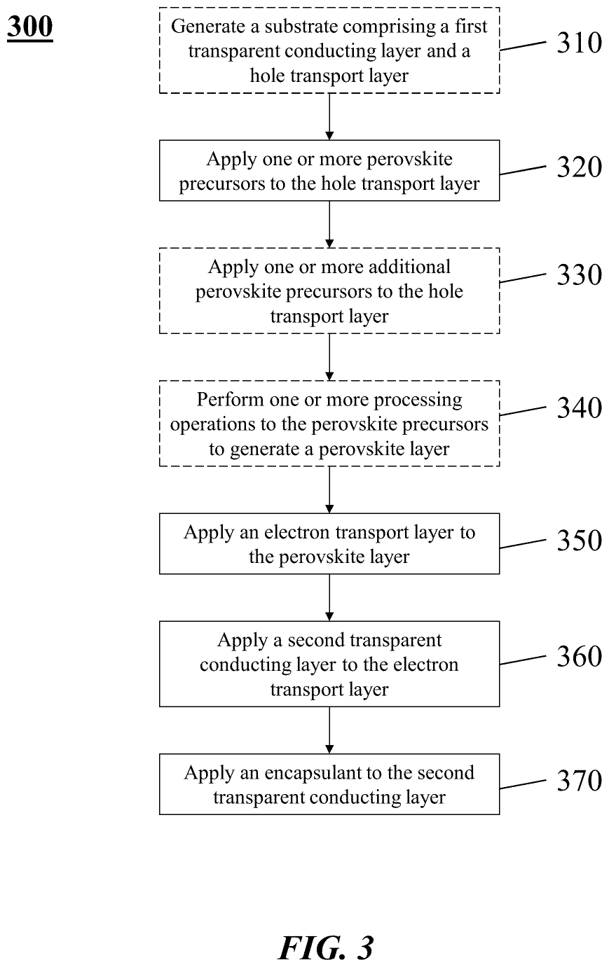

Together, the first TCO layer 110, the HTL 115, the perovskite layer 120, the ETL 125, and the second TCO layer 130 may form a perovskite solar cell. The perovskite solar cell may be disposed on the bottom surface of the top glass sheet 105 through fabrication methods that are described in reference to FIG. 3 through FIG. 10. The perovskite solar cell may have a higher bandgap than the silicon solar cell 140. For example, the perovskite solar cell may have a bandgap of about 1.30, 1.31, 1.32, 1.33, 1.34, 1.35, 1.36, 1.37, 1.38, 1.39, 1.40, 1.41, 1.42, 1.43, 1.44, 1.45, 1.46, 1.47, 1.48, 1.49, 1.50, 1.51, 1.52, 1.53, 1.54, 1.55, 1.56, 1.57, 1.58, 1.59, 1.60, 1.61, 1.62, 1.63, 1.64, 1.65, 1.66, 1.67, 1.68, 1.69, 1.70, 1.71, 1.72, 1.73, 1.74, 1.75, 1.76, 1.77, 1.78, 1.79, 1.80, 1.81, 1.82, 1.83, 1.84, 1.85, 1.86, 1.87, 1.88, 1.89, 1.90, 1.91, 1.92, 1.93, 1.94, 1.95, 1.96, 1.97, 1.98, 1.99, 2.00, 2.01, 2.02, 2.03, 2.04, 2.05, 2.06, 2.07, 2.08, 2.09, 2.10, or greater electron volts (“eV”). In contrast, the silicon solar cell may have a bandgap of about 1.1 eV. Accordingly, the perovskite solar cell may be capable of efficiently converting shorter wavelengths of light to electricity. The perovskite solar cell may be transparent to longer wavelengths of light, which may allow the underlying silicon solar cell to absorb and convert such longer wavelengths of light to electricity. Together, the perovskite solar cell and the silicon solar cell may be capable of efficiently converting a wider spectrum of light to electricity than a single solar cell.

The first TCO layer 110 may be disposed directly on the top glass sheet 105. Depositing the first TCO layer 110 directly on the top glass sheet 105 may prevent damage to the HTL 115 and the perovskite layer 120. The first TCO layer 110 may serve as the positive terminal or cathode of the perovskite solar cell. The first TCO layer 110 may have a thickness of at least about 100 nanometers (nm), 200 nm, 300 nm, 400 nm, 500 nm, 600 nm, 700 nm, 800 nm, 900 nm, 1 micrometer, or more. The first TCO layer 110 may have a thickness of at most about 1 micrometer, 900 nm, 800 nm, 700 nm, 600 nm, 500 nm, 400 nm, 300 nm, 200 nm, 100 nm, or less. The first TCO layer 110 may be made of indium oxide (ITO). The first TCO layer 110 may be made of doped ITO.

The HTL 115 may be disposed on the TCO layer 110. The HTL 115 may facilitate the transport of holes from the perovskite layer 120 to the first TCO layer 110 without compromising transparency and conductivity. In contrast, the HTL 115 may inhibit electron transport. In some embodiments, the HTL 115 is made of one or more nickel oxide layers. In other embodiments, the HTL 115 is made of another appropriate p-type material described in this disclosure. The HTL 115 may have a thickness of at least about 20 nm, 50 nm, 100 nm, 200 nm, 300 nm, 400 nm, 500 nm, 600 nm, 700 nm, 800 nm, 900 nm, 1 micrometer, or more. The HTL 115 may have a thickness of at most about 1 micrometer, 900 nm, 800 nm, 700 nm, 600 nm, 500 nm, 400 nm, 300 nm, 200 nm, 100 nm, 50 nm, 20 nm, or less.

The perovskite layer 120 may be disposed on the HTL 115. The perovskite layer 120 may be the photoactive layer of the perovskite solar cell. That is, the perovskite layer 120 may absorb light and generate holes and electrons that subsequently diffuse into the HTL 115 and the ETL 125, respectively. In some embodiments, the perovskite layer 120 is made of methylammonium lead triiodide, methylammonium lead tribromide, methylammonium lead trichloride, or any combination thereof. In other embodiments, the perovskite layer 120 is made of formamidinium lead triiodide, formamidinium lead tribromide, formamidinium lead trichloride, or any combination thereof. The bandgap of the perovskite layer 120 may be tuned by adjusting the halide content of the methylammonium lead trihalide or formamidinium lead trihalide. The perovskite layer 120 may have a thickness of at least about 250 nm, 300 nm, 400 nm, 500 nm, 600 nm, 700 nm, 800 nm, 900 nm, 1 micrometer, 1.25 micrometers, 1.5 micrometers, 1.75 micrometers, 2 micrometers, or more. The perovskite layer 120 may have a thickness of at most about 2 micrometers, 1.75 micrometers, 1.5 micrometers, 1.25 micrometers, 1 micrometer, 900 nm, 800 nm, 700 nm, 600 nm, 500 nm, 400 nm, 300 nm, 250 nm, or less.

The ETL 125 may be disposed on the perovskite layer 120. The ETL 125 may facilitate the transport of electrons from the perovskite layer 120 to the second TCO layer 130 without compromising transparency and conductivity. In contrast, the ETL 115 may inhibit electron transport. In some embodiments, the ETL 125 is made of phenyl-C61-butyric acid methyl ester (“PCBM”). In other embodiments, the ETL 125 is made of another appropriate n-type material described in this disclosure. The ETL 115 may have a thickness of at least about 10 nm, 20 nm, 30 nm, 40 nm, 50 nm, 60 nm, 70 nm, 80 nm, 90 nm, 100 nm, 200 nm, 300 nm, 400 nm, 500 nm, or more. The HTL 115 may have a thickness of at most about 500 nm, 400 nm, 300 nm, 200 nm, 100 nm, 90 nm, 80 nm, 70 nm, 60 nm, 50 nm, 40 nm, 30 nm, 20 nm, 10 nm, or less.

The second TCO layer 130 may be disposed on the ETL 125. The second TCO layer 130 may serve as the negative terminal or anode of the perovskite solar cell. The second TCO layer 130 may have a thickness of at least about 100 nm, 200 nm, 300 nm, 400 nm, 500 nm, 600 nm, 700 nm, 800 nm, 900 nm, 1 micrometer, or more. The second TCO layer 130 may have a thickness of at most about 1 micrometer, 900 nm, 800 nm, 700 nm, 600 nm, 500 nm, 400 nm, 300 nm, 200 nm, 100 nm, or less. The second TCO layer 110 may be made of indium oxide (ITO). The second TCO layer 110 may be made of doped ITO.

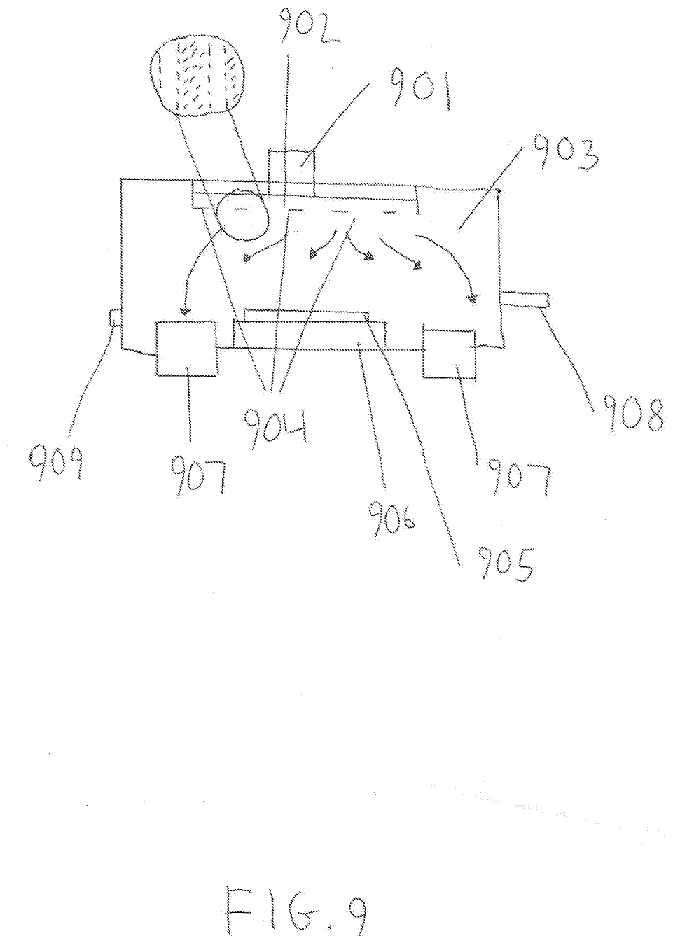

The encapsulant 135 may be disposed between the second TCO layer 130 of the perovskite solar cell and the silicon solar cell 140. The encapsulant 135 may prevent the perovskite solar cell and the silicon solar cell 140 from being exposed to dust and moisture. The encapsulant 135 may electrically isolate the perovskite solar cell from the silicon solar cell 140. The encapsulant 135 may have a high refractive index (e.g., a refractive index greater than 1.4) that matches the refractive index of the TCO layer 130 of the perovskite solar cell and the top silicon nitride or TCO layer of the silicon solar cell 140. Thus of a high refractive index material may decrease transmission losses between the TCO layer 130, encapsulant 135, and silicon solar cell 140, resulting in improved current density of the solar module 100. The user of a high refractive index material may also improve light trapping. The high refractive index material may be ethylene-vinyl-acetate (“EVA”), thermal plastic polyolefin (“TPO”), PDMS, silicone, paraffin, or the like. Example 1 and FIG. 9, which are described below, show the improvements achieved by using certain high refractive index materials in the encapsulant 135.

In general, the silicon solar cell 140 may be a p-type silicon solar cell with a p-type substrate covered by a thin n-type layer (“emitter”), or it may be an n-type silicon solar cell with an n-type substrate covered by a thin p-type emitter. The silicon solar cell 140 may be a monocrystalline silicon solar cell, a polycrystalline silicon solar cell, a PERC silicon solar cell, a HIT silicon solar cell, an interdigitated back contact cell (IBC), or the like.

The silicon solar cell 140 may have a back sheet 145. The back sheet 145 may seal the solar module 100 to prevent moisture ingress. In some cases, the back sheet 145 may be a glass sheet with a top surface and a bottom surface. The top surface of the glass sheet may have a highly reflective coating or textured surface in to further increase light trapping or scattering back in the silicon solar cell 140 and the perovskite layer 120. The glass sheet may be transparent. The glass sheet may be substantially transparent. The transparency of the glass sheet may facilitate bifacial operation of the solar cell. For example, the solar cell can be configured to absorb light from both sides of the solar cell.

The perovskite solar cell and the silicon solar cell 140 may be electrically isolated from each other, and each cell may have its own terminals. That is, the tandem solar module may be a 4-terminal module. The perovskite solar cell and the silicon solar cell 140 may be connected in series or parallel by connecting the terminals in the appropriate manner. In the case of a series connection, the perovskite solar cell and the silicon solar cell may be current-matched. In the case of a parallel connection, the perovskite solar cell and the silicon solar cell may be voltage-matched. Laser scribing can be used to achieve the current matching or voltage matching, e.g., by connecting individually scribed perovskite solar cells in series or parallel to achieve a desired voltage or current. Parallel or series connection between the perovskite solar cells and the silicon solar cell can be made via busbars/electrodes before module lamination. This allows rapid and easy introduction into any existing silicon manufacturing process.

The solar module 100 may have a power conversion efficiency of at least about 25%, 26%, 27%, 28%, 29%, 30%, or more.

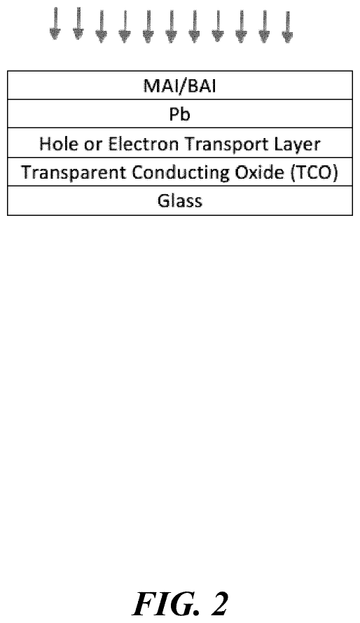

FIG. 2 schematically illustrates how the perovskite layer 120 of FIG. 1 may be formed. A metallic Pb layer may be deposited on the HTL via physical vapor deposition. Next, a methylammonium iodide (MAI) or formamidinium iodide (FAI) may be applied to the metallic Pb layer. Finally, the MAI or FAI may be exposed to iodine gas to form the perovskite layer 120, which may be methylammonium lead triiodide or formamidinium lead triiodide. This and other fabrication processes will be described in more detail in subsequent figures.

### TCO Fabrication

A physical vapor deposition (PVD) process may be used to fabricate the first TCO layer 110 and the second TCO layer 130. The PVD process may be tuned such that the resulting TCO layer is transparent to light (e.g., light with a wavelength from 700 nanometers (“nm”) to 1200 nm for the second TCO layer). For example, the argon pressure and deposition power of the PVD process may be tuned accordingly. For example, the argon pressure can be at about 1 to about 5 millitorr, and the deposition power can be about 20 watts to about 100 watts. Additionally, the thickness of the first TCO layer 110 and the second TCO layers 130 can be set to achieve such transparency. Such transparency may allow the underlying silicon solar cell 140 to absorb as much light as possible that was not already absorbed by the perovskite layer 120, which typically absorbs light with a wavelength from 300 nm to 700 nm.

In fabricating the second TCO layer 130, the PVD process may tend to create defects in the ETL 125 and the perovskite layer 120 due the ultraviolet light and argon/oxygen ions generated by the plasma during the process. Such defects may degrade the performance of the perovskite layer 120 as an electron-hole pair absorber. For example, the perovskite layer 120 may exhibit a lower open circuit voltage and a lower fill factor as the result of such defects. It may be beneficial to minimize the creation of such defects.

In one embodiment, the damage described above can be minimized by first creating a buffer layer of TCO on the ETL 125 through a low-power PVD process. The power during the low-power PVD process may be at most about 0.60, 0.55, 0.50, 0.45, 0.40, 0.35, 0.30, 0.25, 0.20, 0.15, 0.10, 0.05, or less Watts per square centimeter (“W/cm²”). The buffer layer may be at least about 5, 10, 15, 20, 25, 30, 35, 40, 45, 50, 55, 60, 65, or more nm thick. The buffer layer may be at most about 65, 60, 55, 50, 45, 40, 35, 30, 25, 20, 15, 10, 5, or less nm thick. The ultraviolet damage is normally generated by high power ions that penetrate deep into the bulk of the ETL 125 and the perovskite layer 120, breaking or damaging molecular bonds and causing degradation in both the open circuit voltage and series resistance. The use of a low-power PVD to create the buffer layer may block high energy ions in subsequent process steps from reaching the ETL 125 and the perovskite layer 125.

A bulk layer of TCO may be deposited on the buffer layer of TCO at a deposition energy of at most 1.00, 0.95, 0.90, 0.85, 0.80, 0.75, 0.70, 0.65, 0.60, 0.55, 0.50, 0.45, or less W/cm².

In some cases, an ultrathin layer of silver may be deposited at the interface between the ETL 125 and the second TCO layer 130 through an evaporation, sputtering, or atomic layer deposition. The ultrathin layer of silver may be at most about 15, 14, 13, 12, 11, 10, 9, 8, 7, 6, 5, 4, 3, 2, or 1 angstroms thick. The ultrathin layer of silver may act as a barrier against ultraviolet light or plasma during PVD of the second TCO layer 130. In some cases, a post-anneal may be performed on the second TCO layer to partially repair some of the damage caused by the ultraviolet light or plasma during the PVD process. The post-anneal may be performed at 100 degrees Celsius for 2 to 4 minutes.

A bulk layer of TCO may be deposited on the buffer layer of TCO at a deposition energy of at most 0.90, 0.85, 0.80, 0.75, 0.70, 0.65, 0.60, 0.55, 0.50, 0.45, or less W/cm².

FIG. 3 is a flow chart of a fabrication process 300 for forming a perovskite photovoltaic. The process 300 may optionally comprise generating a substrate comprising a first transparent conducting layer and a hole transport layer (310). In some cases, a pre-formed substrate may instead be provided.

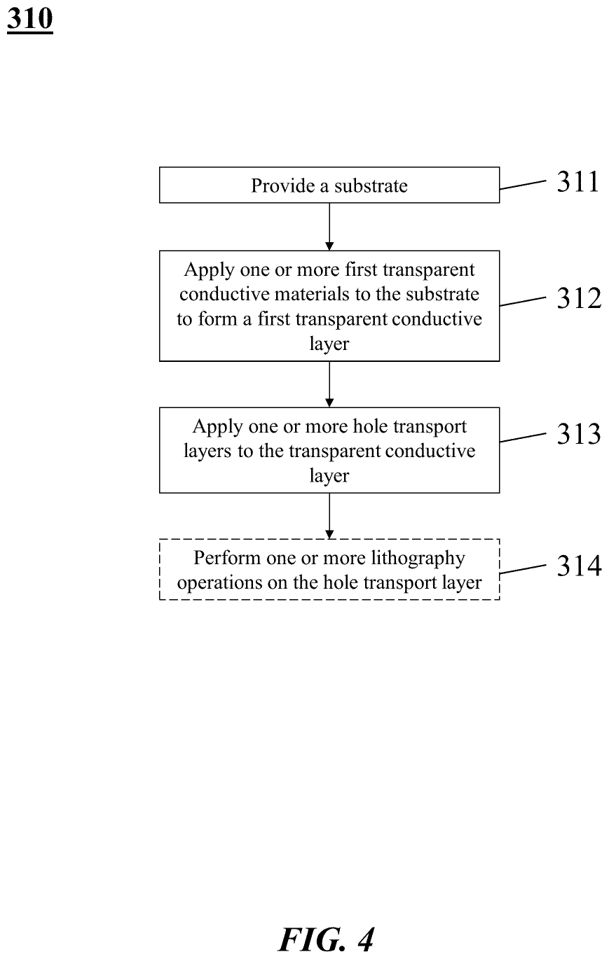

FIG. 4 is a flowchart of operation 310 of FIG. 3. Operation 310 may comprise providing a substrate (311). The substrate may be a transparent substrate. The substrate may comprise a silicon-based glass (e.g., an amorphous silicon dioxide, a doped silicon dioxide, etc.), a transparent conductive oxide, a ceramic, a chalcogenide glass, a polymer (e.g., a transparent plastic, poly(methyl methacrylate, etc.), or the like, or any combination thereof. The substrate may comprise a top surface of a solar module. For example, the substrate may be a top glass of a silicon solar panel assembly. The substrate may be textured and/or patterned. For example, the substrate may comprise nano-scale texturing configured as an antireflective coating and an adhesion surface. In another example, the substrate may comprise patterning configured to generate photonic channels. In another example, the substrate may comprise pre-patterned portions with electrodes for removing energy from the solar cell (e.g., a top contact grid layout). The substrate may have an area of at least about 0.1, 0.5, 1, 2, 3, 4, 5, 6, 7, 8, 9, 10, 11, 12, 13, 14, 15, 20, 25, or more square meters. The substrate may have an area of at most about 25, 20, 15, 14, 13, 12, 11, 10, 9, 8, 7, 6, 5, 4, 3, 2, 1, 0.5, 0.1, or fewer square meters. The substrate may be a large format substrate. For example, the substrate can be a 10^{th} generation substrate.

Operation 310 may comprise applying one or more first transparent conductive materials to the substrate to form a first transparent conductive layer (312). The first transparent conducting layer may comprise a transparent conductive oxide (e.g., indium tin oxide (ITO), indium zinc oxide, aluminum zinc oxide, indium cadmium oxide, etc.), a transparent conductive polymer (e.g., poly(3,4-ethylenedioxythiophene) (PEDOT), poly(3,4-ethylenedioxythiophene):poly(styrene sulfonate) (PEDOT:PSS), poly(4,4-dioctyl cyclopentadithiophene), etc.), carbon nanotubes, graphene, nanowires (e.g., silver nanowires), metallic grids (e.g., grid contacts comprising metals), thin films (e.g., thin metal films), conductive grain boundaries, or the like, or any combination thereof. The transparent conducting layer may have a full spectrum transparency of at least about 20%, 30%, 40%, 50%, 60%, 70%, 75%, 80%, 85%, 90%, 95%, 96%, 97%, 98%, 99%, 99.9%, or more. The transparent conducting layer may have a full spectrum transparency of at most about 99.9%, 99%, 98%, 97%, 96%, 95%, 90%, 85%, 80%, 75%, 70%, 60%, 50%, 40%, 30%, 20%, or less. The transparent conducting layer may have a full spectrum transparency in a range as defined by any two of the proceeding values. For example, the transparent conducting layer can have a full spectrum transparency of 75% to 85%. The transparent conducting layer may have a transparency over a spectral band of at least about 20%, 30%, 40%, 50%, 60%, 70%, 75%, 80%, 85%, 90%, 95%, 96%, 97%, 98%, 99%, 99.9%, or more. The transparent conducting layer may have a transparency over a spectral band of at most about 99.9%, 99%, 98%, 97%, 96%, 95%, 90%, 85%, 80%, 75%, 70%, 60%, 50%, 40%, 30%, 20%, or less. For example, the transparent conducting layer can have a transmission of 85% over the wavelength range from 400 nm to 1200 nm. Methods for forming transparent conductive oxide layers are described elsewhere herein.

Operation 310 may comprise applying one or more hole transport layers to the transparent conductive layer (313). The one or more hole transport layers may be configured to shuttle holes from an absorbing layer to the transparent conductive layer and out of the solar module. The one or more hole transport layers may comprise organic molecules (e.g., 2,2′,7,7′-Tetrakis[N,N-di(4-methoxyphenyl)amino]-9,9′-spirobifluorene (Spiro-OMeTAD)), inorganic oxides (e.g., nickel oxide (NiOₓ), copper oxide (CuOₓ), cobalt oxide (CoOₓ), chromium oxide (CrOₓ), vanadium oxide (VOₓ), tungsten oxide (WO)), molybdenum oxide (Mo Ox), copper aluminum oxide (CuAlO₂), copper chromium oxide (CuCrO₂), copper gallium oxide (CuGaO₂), etc.), inorganic chalcogenides (e.g., copper iodide (CuI), copper indium sulfide (CuInS₂), copper zinc tin sulfide (CuZnSnS₄), cupper barium tin sulfide (CuBaSnS₄), etc.) other inorganic materials (e.g., copper thiocyanate (CuSCN), etc.), organic polymers, or the like, or any combination thereof. For example, a glass substrate covered in indium tin oxide can be coated with nickel oxide to form a hole transport layer on the transparent conducting layer.

Operation 310 may optionally comprise performing one or more lithography operations on the hole transport layer (314). The one or more lithography operations may comprise optical lithography (e.g., (extreme) ultraviolet lithography, x-ray lithography, laser scribing, etc.), electron beam lithography, ion beam lithography, nanoimprint lithography, other direct writing processes (e.g., dip-pen lithography, inkjet printing), or the like, or any combination thereof. For example, a plurality of features can be inscribed onto the hole transport layer using a laser scribe. The one or more lithography operations may comprise the addition and/or subtraction of features. For example, features can be cured and made permanent. In another example, features can be formed by the removal of material from the target.

Returning to FIG. 3, the process 300 may comprise applying one or more perovskite precursors to the hole transport layer (320). The applying may comprise chemical vapor deposition (CVD), plasma enhanced CVD, atomic layer deposition, spin coating, dip coating, doctor blading, drop casting, centrifugal casting, chemical solution deposition, sol-gel deposition, plating, physical vapor deposition, thermal evaporation, molecular beam epitaxy, sputtering, pulsed laser deposition, cathodic arc deposition, ultrasonic spray-on, inkjet printing, or the like, or any combination thereof. The applying may comprise the application of a single perovskite precursor at a time. For example, a first perovskite precursor can be evaporated onto the hole transport layer, and subsequently a second perovskite precursor can be sprayed onto the first precursor. The applying may comprise applying a plurality of precursors at one time. For example, an inkjet printer can apply a solution comprising a plurality of precursors. The process 300 may optionally comprise applying one or more additional perovskite precursors to the hole transport layer (330). The additional perovskite layers may be applied in the same way as in operation 320. For example, a first precursor can be deposited by physical vapor deposition, and subsequently a second precursor can be deposited by physical vapor deposition. Alternatively, the additional perovskite layer may be applied in a different way from operation 320. For example, a first perovskite precursor can be deposited by physical vapor deposition while a second perovskite precursor can be deposited by ultrasonic spray. Operation 330 may be repeated a plurality of times. For example, a plurality of additional perovskite precursors can be applied to the hole transport layer in a plurality of operations.

The ultrasonic spray-on application may comprise the use of a plurality of spray nozzles. A plurality of different types of spray nozzles may be tested for formation of a predetermined uniformity and/or thickness of the film deposited by the spray nozzle, and an optimal spray nozzle may be selected from the plurality of different types of spray nozzles. Once an optimal spray nozzle is selected, a plurality of that type of nozzle may be used in the ultrasonic spray-on application. The plurality of nozzles may form a bank of nozzles configured to spray over a large area to improve throughput and efficiency. The bank of nozzles may be a strip of nozzles (e.g., a line of nozzles across a single dimension), a two-dimensional arrangement of nozzles (e.g., nozzles distributed over a rectangular shape), a three-dimensional arrangement of nozzles (e.g., a plurality of nozzles distributed in three dimensions). Use of an ultrasonic spray-on application can enable a roll to roll inline fabrication process. In the roll to roll inline fabrication process, a series of nozzle banks can each sequentially add different layers to a substrate, the substrate can be processed (e.g., annealed, laser scribed, etc.), and a finished photovoltaic cell can be generated on a single line. Using a roll to roll process can result in significant improvements in cost and speed of production as compared to step by step manufacture processes.

The one or more perovskite precursors may comprise one or more lead halides (e.g., lead fluoride, lead chloride, lead bromide, lead iodide, etc.), lead salts (e.g., lead acetates, lead oxides, etc.), other metal salts (e.g., manganese halides, tin halides, metal oxides, metal halides, etc.), organohalides (e.g., formamidinium chloride, formamidinium bromide, formamidinium iodide, methylammonium chloride, methylammonium bromide, methylammonium iodide, butylammonium halides, etc.), alkali metal salts (e.g., alkali metal halides, etc.), alkali earth metal salts (e.g., alkali earth metal halides, etc.), perovskite nanoparticles, or the like, or any combination thereof. A plurality of perovskite precursors can be used as the one or more perovskite precursors. For example, both methylammonium iodide and butylammonium iodide can be used as perovskite precursors. In this example, the methylammonium iodide can be at about a 1:99, 10:90, 20:80, 30:70, 40:60, 50:50, 60:40, 70:30, 80:20, 10:90, or 99:1 ratio with the butylammonium iodide. In another example, mixtures of lead halides can be used as a portion of the perovskite precursors. Using different mixtures of lead halides may permit tuning of the bandgap of the perovskite layer. For example, using different mixtures of lead (II) bromide and lead (II) iodide can result in different bandgaps. Using different amounts of lead (II) chloride can affect the crystal stability of the perovskite layer and can prevent phase segregation within the layer. The amount of lead (II) chloride added may be greater than the amount of lead (II) bromide added by weight. The amount of lead (II) chloride added may be less than the amount of lead (II) bromide added by weight. The amount of lead (II) chloride added may be the same as the amount of lead (II) bromide added by weight. The amount of lead (II) iodide soluble in a solution may be related to the amount of lead (II) bromide and lead (II) chloride in the solution. For example, adding in more lead (II) bromide and lead (II) chloride to a solution of lead (II) iodide can improve solubility of the lead (II) iodide and result in decreased particulate in the perovskite layer.

The one or more perovskite precursors may be one or more perovskite precursor solutions. For example, a lead (II) iodide solution in a solution of dimethyl sulfoxide can be a perovskite precursor. A perovskite precursor may be in a solution of at least about 0.1, 0.5, 1, 2, 3, 4, 5, 6, 7, 8, 9, 10, 11, 12, 13, 14, 15, 20, 25, 30, 35, 40, 45, 50, 55, 60, 65, 70, 75, 80, 85, 90, 95, 99, or more weight percent perovskite precursor. A perovskite precursor may be in a solution of at most about 99, 95, 90, 85, 80, 75, 70, 65, 60, 55, 50, 45, 40, 35, 30, 25, 20, 15, 14, 13, 12, 11, 10, 9, 8, 7, 6, 5, 4, 3, 2, 1, 0.5, 0.1, or less weight percent perovskite precursor. The solution may comprise one or more solvents. Examples of solvents include, but are not limited to, polar solvents (e.g., water, dimethyl sulfoxide, dimethylformamide, ethers, esters, acetates, acetone, etc.), non-polar solvents (e.g., hexanes, toluene, etc.), or the like, or any combination thereof. Proper mixing of the solvent as well as solvent composition can contribute to controlled solvent removal speeds and thus impact grain development as well as bulk defect formation.

The one or more perovskite precursors may comprise one or more additives. The addition of the one or more additives may be configured to reduce and/or eliminate defects within perovskite layers as prepared elsewhere herein. The one or more additives may comprise one or more recrystallization solvents. The one or more recrystallization solvents may be added to a solution comprising the one or more perovskite precursors. The one or more recrystallization solvents may be applied after deposition of the one or more perovskite precursors and/or after an annealing of the one or more perovskite precursors. For example, a lead halide precursor can be applied and subsequently a recrystallization solvent can be applied, and the perovskite precursors can be further annealed to orient the lead halide precursor for better methylammonium iodide integration. Examples of recrystallization solvents include, but are not limited to, halobenzenes (e.g., chlorobenzene, bromobenzene, etc.), haloforms (e.g., chloroform, iodoform, etc.), ethers (e.g., diethyl ether), or the like, or any combination thereof.

A variety of parameters may be tuned to provide a predetermined perovskite layer. Examples of parameters include, but are not limited to, perovskite precursor solution application temperature, volume application rate, ultrasonic power of an ultrasonic spray-on instrument, lateral speed of precursor application (e.g., the speed of a substrate moving through an applicator), applicator height (e.g., the distance from an applicator to the substrate, environmental factors (e.g., humidity, reactive gas content, temperature, etc.), wetting surface energy, or the like, or any combination thereof. Any portion of process 300, including the application of the perovskite precursors, may take place in a controlled environment. The controlled environment may have a relative humidity of at least about 10%, 20%, 30%, 40%, 50%, 60%, 70%, 80%, 90%, 99%, or more. The controlled environment may have a relative humidity of at most about 99%, 90%, 80%, 70%, 60%, 50%, 40%, 30%, 20%, 10%, or less. The controlled environment may comprise a controlled atmosphere. The controlled atmosphere may comprise inert gasses (e.g., nitrogen, noble gases, etc.). The controlled atmosphere may have an oxygen content of at least about 1 part per million (ppm), 10 ppm, 50 ppm, 100 ppm, 500 ppm, 1,000 ppm, 5,000, ppm, 1%, 5%, 10%, 15%, 20%, or more. The controlled atmosphere may have an oxygen content of at most about 20%, 15%, 10%, 5%, 1%, 5,000 ppm, 1,000 pm, 500 ppm, 100 ppm, 50 ppm, 10 ppm, 1 ppm, or less. The controlled atmosphere may be at a temperature of at least about 15, 20, 25, 30, 35, 40, 45, 50, 55, 60, 65, 70, 75, 80, 85, 90, 95, 100, 105, 110, 115, 120, 125, 130, 135, 140, 145, 150, 160, 170, 180, 190, 200, or more degrees Celsius. The controlled atmosphere may be at a temperature of at most about 200, 190, 180, 170, 160, 150, 145, 140, 135, 130, 125, 120, 115, 110, 105, 100, 95, 90, 85, 80, 75, 70, 65, 60, 55, 50, 45, 40, 35, 30, 25, 20, 15, or less degrees Celsius.

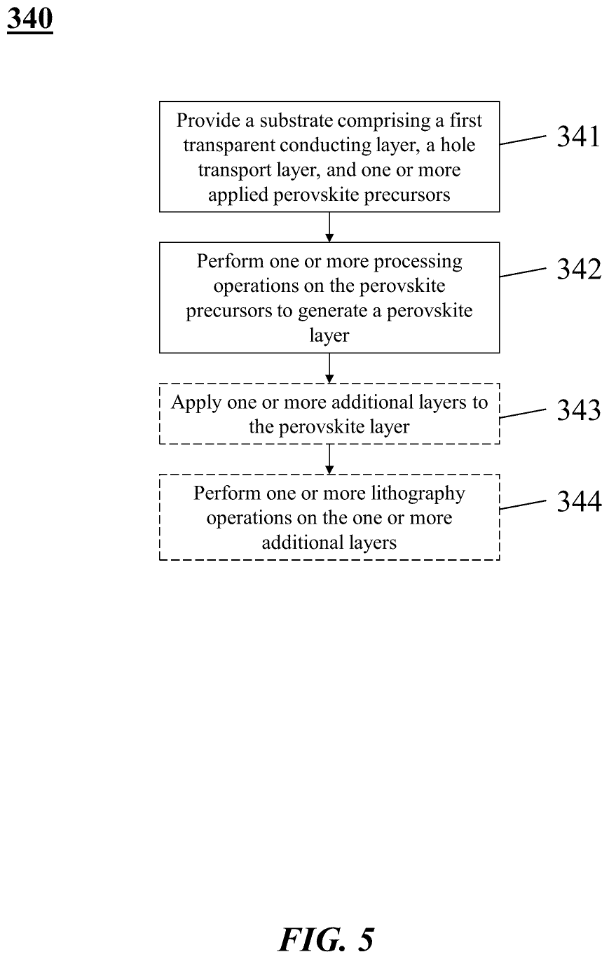

The process 300 may comprise performing one or more processing operations to the perovskite precursors to generate a perovskite layer (340). If the perovskite precursors are instead deposited as a completed perovskite layer, operation 340 may be omitted. FIG. 5 is a flowchart of operation 340 of FIG. 3. Operation 340 may comprise providing a substrate comprising a first transparent conducting layer, a hole transport layer, and one or more applied perovskite precursors (341). The substrate may be a result of operations 310-330 of process 300.

Operation 340 may comprise performing one or more processing operations on the perovskite precursors to generate a perovskite layer (342). The one or more processing operations may comprise annealing, light exposure (e.g., ultraviolet light exposure), agitation (e.g., vibration), functionalization (e.g., surface functionalization), electroplating, template inversion, or the like, or any combination thereof. For example, a substrate with perovskite precursors can be annealed to form a perovskite layer from the precursors. In another example, perovskite precursors can be annealed and subsequently functionalized. The annealing may be annealing under inert atmosphere (e.g., argon atmosphere, nitrogen atmosphere). The annealing may be under a reactive atmosphere (e.g., an atmosphere comprising a reagent (e.g., methylammonium)). The annealing may be at a temperature of at least about 15, 20, 25, 30, 35, 40, 45, 50, 55, 60, 65, 70, 75, 80, 85, 90, 95, 100, 105, 110, 115, 120, 125, 130, 135, 140, 145, 150, 160, 170, 180, 190, 200, or more degrees Celsius. The annealing may be at a temperature of at most about 200, 190, 180, 170, 160, 150, 145, 140, 135, 130, 125, 120, 115, 110, 105, 100, 95, 90, 85, 80, 75, 70, 65, 60, 55, 50, 45, 40, 35, 30, 25, 20, 15, or less degrees Celsius. The annealing may be at a temperature range as defined by any two of the proceeding values. For example, the annealing can be at a temperature of 90 to 120 degrees Celsius.

Operation 340 may comprise applying one or more additional layers to the perovskite layer (343). The one or more additional layers may comprise one or more additional perovskite layers. For example, a second perovskite layer with a different bandgap can be applied to the first perovskite layer. The one or more additional layers may comprise one or more additional perovskite precursors. For example, iodine gas can be applied to form an iodine layer on a perovskite and/or perovskite precursor layer. The one or more additional layers may comprise one or more washing operations. A washing operation may comprise an application of a solvent to the perovskite layer. Examples of solvents include, but are not limited to, water, non-polar organic solvents (e.g., hexanes, toluene, etc.), polar organic solvents (e.g., methanol, ethanol, isopropanol, acetone, etc.), ionic solvents, or the like. The one or more additional layers may comprise one or more passivating layers. A passivating layer may comprise a reagent configured to passivate and/or stabilize the perovskite layer. For example, an application of a solution comprising phenethylammonium iodide can passivate and stabilize the grains of the perovskite layer.

Operation 340 may comprise performing one or more lithography operations on the one or more additional layers and/or the perovskite layer (344). The one or more lithography operations may be one or more lithography operations as described elsewhere herein. For example, a laser scribe can be used to generate features on a perovskite layer.

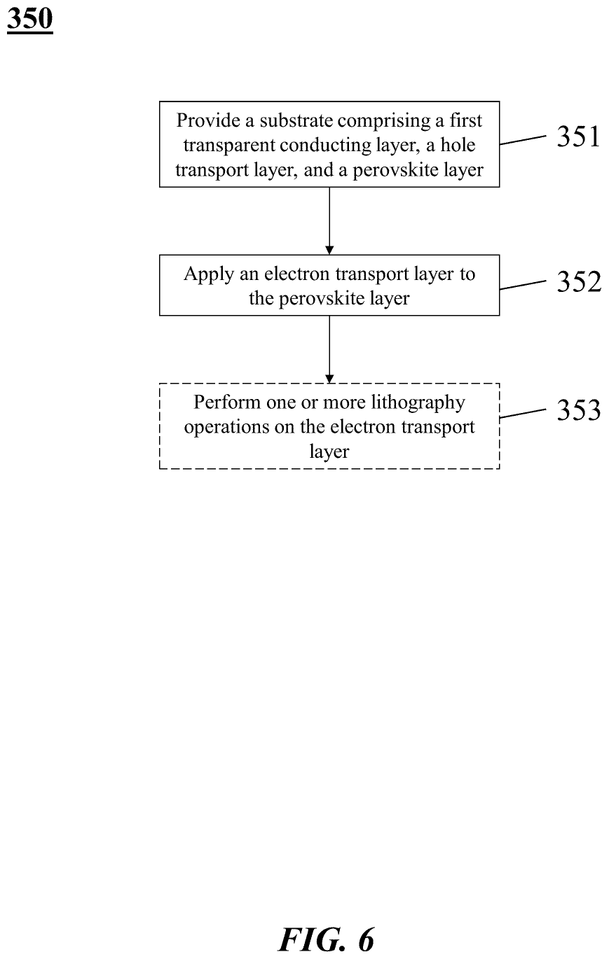

Returning to FIG. 3, the process 300 may comprise applying an electron transport layer to the perovskite layer (350). FIG. 6 is a flow chart of operation 350 of FIG. 3. Operation 350 may comprise providing a substrate comprising a first transparent conducting layer, a hole transport layer, and a perovskite layer (351). The substrate may be a substrate generated by operations 310-340 of FIG. 3.

Operation 350 may comprise applying an electron transport layer to the perovskite layer (352). The electron transport layer may be applied by methods and systems as described elsewhere herein (e.g., physical vapor deposition, etc.). The electron transport layer may comprise a material with a conduction band minimum less than that of the perovskite layer. For example, if the perovskite layer has a conduction band minimum of −3.9 eV, the electron transport layer may have a conduction band minimum of −4 eV. Examples of electron transport layer materials include, but are not limited to titanium oxide (e.g., TiO₂), zinc oxide, tin oxide, tungsten oxide, indium oxide, niobium oxide, iron oxide, cerium oxide, strontium titanium oxide, zinc tin oxide, barium tin oxide, cadmium selenide, indium sulfide, lead iodide, organic molecules (e.g., phenyl-C61-butyric acid methyl ester (PCBM), poly(3-hexylthiophene-2,5-diyl) (P3HT), etc.), lithium fluoride, buckminsterfullerene (C60), or the like, or any combination thereof. Operation 350 may optionally comprise performing one or more lithography operations on the electron transport layer (353). The one or more lithography operations may be one or more lithography operations as described elsewhere herein. For example, a laser scribe can be used to generate features on the electron transport layer.

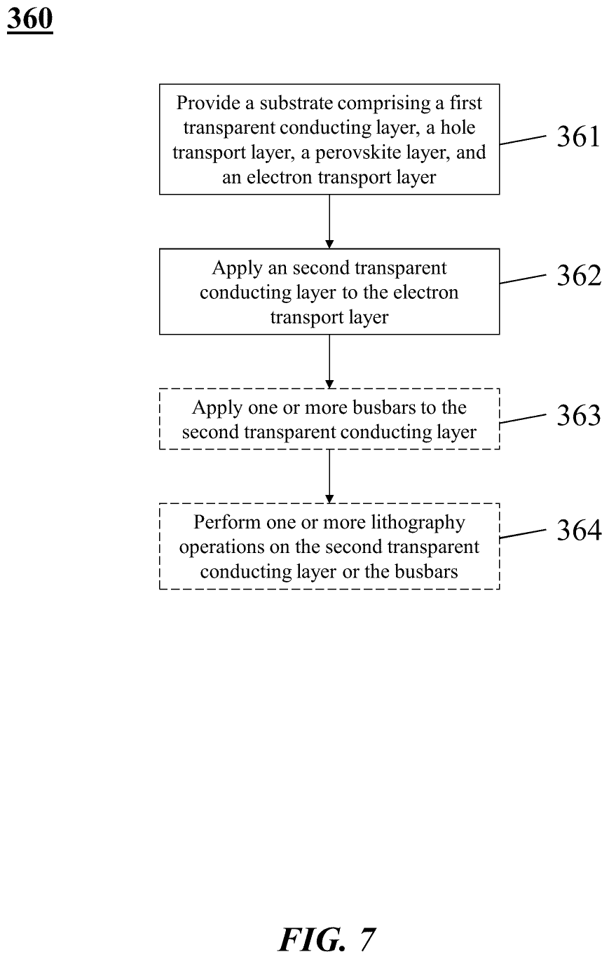

Returning to FIG. 3, the process 300 may comprise applying a second transparent conducting layer to the electron transport layer (360). FIG. 7 is a flow chart of operation 360 of FIG. 3. Operation 360 may comprise providing a substrate comprising a first transparent conducting layer, a hole transport layer, a perovskite layer, and an electron transport layer (371). The substrate may be a substrate generated by operations 310-350 of FIG. 3.

Operation 360 may comprise applying a second transparent conducting layer to the electron transport layer (362). The second transparent conducting layer may be of the same type as the first transparent conducting layer. For example, both the first and second transparent conducting layers may be indium tin oxide. The second transparent conducting layer may be of a different type as the first transparent conducting layer. The second transparent conducting layer may be deposited as described elsewhere herein (e.g., physical vapor deposition, etc.).

Operation 360 may comprise applying one or more busbars to the second transparent conducting layer (363). The one or more busbars may be applied as busbars (e.g., preformed busbars are applied to the second transparent conducting layer). For example, a mask can be used to form the busbars from an evaporation process. The one or more busbars may be applied as a solid film and subsequently formed into the busbars. For example, a silver film can be deposited onto the second transparent conductive layer and etched to form the busbars. In another example, a laser scribe can be used to form the busbars from a silver film. Operation 360 may optionally comprise performing one or more lithography operations on the electron transport layer (364). The one or more lithography operations may be one or more lithography operations as described elsewhere herein. For example, a laser scribe can be used to generate features on the second transparent conducting layer. The busbars may be attached to at least about 2, 3, 4, or more terminals. The busbars may be attached to at most about 4, 3, 2, or less terminals. The terminals may be configured to form a parallel connection with one or more additional photovoltaic modules. The terminals may be configured to form a series connection with one or more additional photovoltaic modules. The terminals may be scribed (e.g., laser scribed). The terminals may be configured to enable connection of a perovskite photovoltaic device with another photovoltaic device prior to a lamination of the two photovoltaic devices. For example, a perovskite photovoltaic device can be connection via two terminals to a silicon photovoltaic device.

Returning to FIG. 3, the process 300 may comprise applying an encapsulant to the second transparent conducting layer (370). The encapsulant may be configured to reduce or substantially eliminate an exposure of the perovskite layer to one or more reactive species. Examples of reactive species include, but are not limited to, oxygen, water, and polar molecules (e.g., polar volatile organic compounds, acids, etc.). The encapsulant may be substantially transparent. For example, the encapsulant may be transparent in a same region of light as the transparent conducting layer. Examples of encapsulants include, but are not limited to, polymers (e.g., butyl rubber, poly(methyl methacrylate), polycarbonate, polyethylene, polystyrene, thermoplastic olefins, polypropylene, etc.), waxes (e.g., paraffin wax), metals (e.g., iron, copper), semiconductors (e.g., wide bandgap semiconductors (e.g., zinc oxide, titanium oxide)), or the like, or any combination thereof.

The encapsulant may be applied across the second transparent conducting layer (e.g., applied to the whole layer), to a portion of the second transparent conducting layer (e.g., a portion of the layer), to the edges of the second transparent conducting layer (e.g., as a seal over the entire stack of layers), or the like, or any combination thereof. For example, the encapsulant can be applied on the edge of the full stack of layers to prevent moisture and oxygen diffusion into the stack. The encapsulant may be applied to the first conductive layer as well as the second conductive layer. For example, the substrate can comprise an encapsulant between the substrate and the first conducting layer. Example 3 below describes the use of PDMS as an encapsulant.

Subsequently to operation 370, the completed stack (e.g., the substrate, perovskite layer, and other layers) may be used as a front panel for an additional photovoltaic module. For example, the completed stack can be configured to be a front junction of a two-junction photovoltaic module. The completed stack may be configured for use as a substrate for an additional stack. For example, the stack can be used as the initial substrate for growth of a silicon photovoltaic module. The stack may be laminated to a second photovoltaic cell. The stack may be laminated at a temperature of at least about 15, 20, 25, 30, 35, 40, 45, 50, 55, 60, 65, 70, 75, 80, 85, 90, 95, 100, 105, 110, 115, 120, 125, 130, 135, 140, 145, 150, 160, 170, 180, 190, 200, or more degrees Celsius. The stack may be laminated at a temperature of at most about 200, 190, 180, 170, 160, 150, 145, 140, 135, 130, 125, 120, 115, 110, 105, 100, 95, 90, 85, 80, 75, 70, 65, 60, 55, 50, 45, 40, 35, 30, 25, 20, 15, or less degrees Celsius.

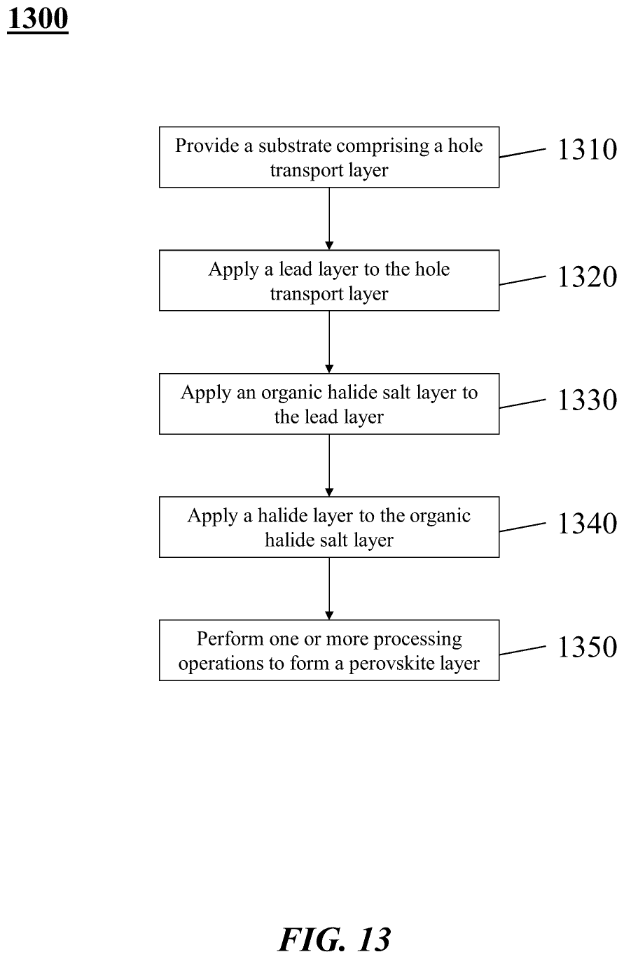

FIG. 13 is a flow chart of a fabrication process 1300 for forming a perovskite layer. The process 1300 may be one embodiment of operations 320-340 of FIG. 3. The process 1300 may comprise providing a substrate comprising a hole transport layer (1310). The substrate may also comprise a transparent conducting layer as described elsewhere herein. The hole transport layer may be a hole transport layer as described elsewhere herein. The substrate may be a substrate as described elsewhere herein.

The process 1300 may comprise applying a lead layer to the hole transport layer (1320). The lead layer may comprise lead metal (e.g., lead (0)), lead salts (e.g., lead (II) acetate, lead (II) halide, lead (I) salts, etc.), or any combination thereof. For example, a metallic lead layer may be deposited onto the hole transport layer, and a layer of lead (II) acetate may be applied to the lead layer. The lead layer may be deposited as described elsewhere herein. For example, the lead may be deposited by physical vapor deposition. The lead layer may be deposited by the same deposition method and/or deposition machinery as the hole transport layer. For example, the same physical vapor deposition instrument can be used to deposit both the hole transport layer as well as the lead layer.

The process 1300 may comprise applying an organic halide salt layer to the lead layer (1330). The organic halide may be an organic halide as described elsewhere herein. For example, a mixture of methylammonium iodide, methylammonium chloride, and formamidinium iodide can be applied to the lead layer. The organic halide layer may be applied by a deposition process as described elsewhere herein. For example, the organic halide can be applied by a spin coating process, an ultrasonic spray-on process, or the like.

The process 1300 may comprise applying a halide layer to the organic halide layer (1340). The halide layer may comprise halides (e.g., fluorine, chlorine, bromine, iodine, etc.), oxyhalides (e.g., chlorate, etc.), other halide containing compounds, or the like, or any combination thereof. For example, the halide layer may comprise iodine. In another example, the halide layer may be iodine. The halide layer may be applied to the organic halide salt layer by deposition processes as described elsewhere herein. The halide can be applied as a gas. For example, iodine can be sublimated and applied as a gas to the organic halide salt layer. The halide can be applied evenly across the surface of the organic halide salt layer. To apply the halide uniformly, a variety of different application devices can be used. An example of an application device may be a ‘shower head’ (e.g., an application head comprising a plurality of holes. An example of a shower head for application of a perovskite precursor may be found in FIG. 9. Another example of an application device may be a bar comprising one or more nozzles that can be translated across the surface of the substrate. For example, a bar of the same width as the substrate can be moved across the substrate to deposit an even coat of halide.

The process 1300 may comprise performing one or more processing operations to form a perovskite layer (1350). The perovskite layer may be a perovskite layer as described elsewhere herein (e.g., a perovskite layer from FIG. 3). The one or more processing operations may be one or more processing operations as described elsewhere herein. For example, the lead layer with a lead acetate layer deposited on top of it, a methylammonium iodide/formamidinium iodide layer, and an iodide layer can be annealed together at a temperature of 90-120 degrees Celsius to form a methylammonium/formamidinium lead iodide perovskite layer. The one or more processing operations may comprise a wash. The wash may comprise use of one or more solvents described elsewhere herein. The wash may be configured to remove unreacted precursors from the perovskite layer. For example, an isopropanol was can be performed to remove residual organic halide salts. The one or more processing operations may comprise one or more treatments. Examples of treatments include, but are not limited to, application of phenethylammonium iodide, thiocyanate washes, other passivation and/or stabilization processes, or the like, or any combination thereof.

In another aspect, the present disclosure provides a method of generating a perovskite layer comprising spraying on a solution comprising precursors for the perovskite layer. A quench solution may be applied to the precursors to form the perovskite layer. The solution may comprise all of the precursors for the perovskite layer. For example, the solution can comprise a lead halide, an organohalide, and a halide. The solution may comprise perovskite precursors as described elsewhere herein. The solution may be applied by processes as described elsewhere herein. For example, the solution can be applied by ultrasonic spray on techniques. The solution may be treated after application. For example, the solution can be heated to remove solvent from the solution. The solution may not be treated after application. The quench solution may be applied to a solution (e.g., a precursor solution). The quench solution may be applied to dried precursors. The quench solution may comprise an antisolvent (e.g., a solvent that the perovskite precursors are less soluble in than the solvent for the precursor solution). Examples of antisolvents include, but are not limited to polar solvents (e.g., alcohols, acetone, etc.), long-chain non-polar solvents (e.g., octadecene, squalene, etc.), or the like, or any combination thereof. The quench solution may be applied as described elsewhere herein. For example, the quench solution may be applied by ultrasonic spray-on techniques.

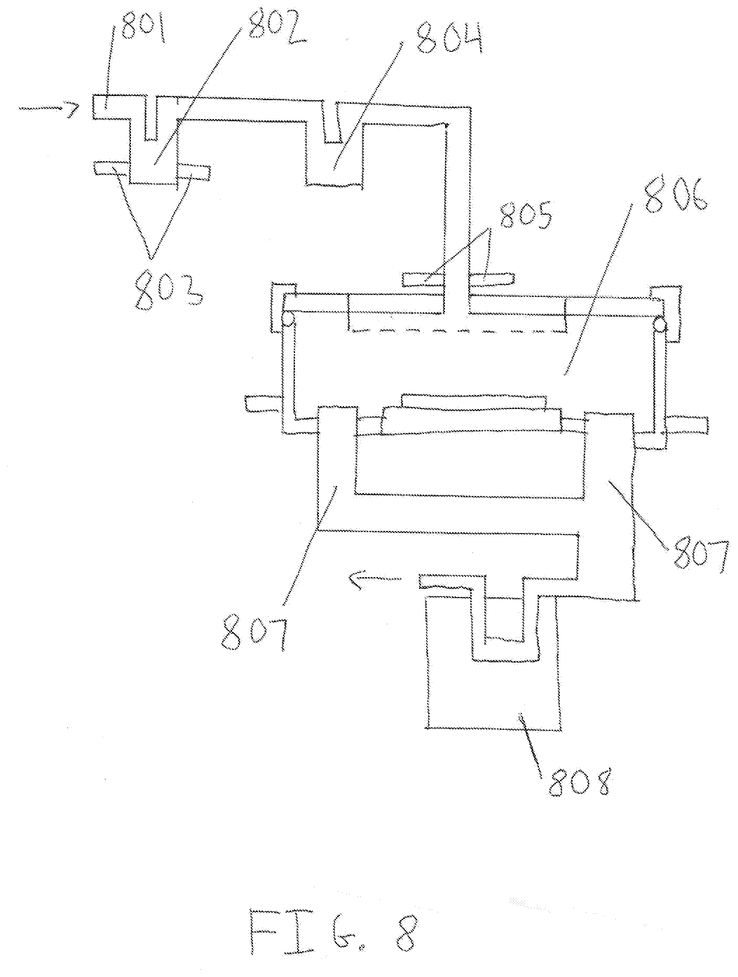

FIG. 8 schematically illustrates a perovskite precursor deposition chamber. Gas can flow from inlet 801 into chamber 802. The gas may be an inert gas (e.g., nitrogen, argon, etc.). The chamber 802 may comprise one or more perovskite precursors. For example, the chamber can contain solid iodine. In another example, the chamber can contain liquid bromine. The gas can be configured as a carrier gas for the one or more perovskite precursors in the reservoir. For example, the gas can carry sublimated iodine out of the chamber. The chamber may comprise an optical sensor assembly 803. The optical sensor assembly may comprise a light source and a detector as described elsewhere herein. For example, the optical sensor assembly may comprise a green laser and a photodiode detector. The gas may pick up the one or more perovskite precursors from chamber 802 and flow into to chamber 804. Chamber 804 may be configured to regulate a flow of the gas and/or the one or more perovskite precursors from chamber 802. The chamber may be configured to prevent outflow from the deposition chamber 806. The chamber 804 may be configured as a bubbler (e.g., a water bubbler, a mercury bubbler, etc.), a mass flow controller (e.g., an iodine mass flow controller, etc.), or the like, or any combination thereof. The gas may flow from chamber 804 through an additional optical sensor assembly 805 to chamber 806. The optical sensor assembly 805 may comprise a light source and a detector as described elsewhere herein. For example, the optical sensor assembly may comprise a green laser and a photodiode detector. The chamber may be a chamber as described elsewhere herein. For example, the chamber may be a chamber as described in FIG. 9. The chamber 808 may be made of or coated with a material resistant to a halide gas. For example, the chamber may be made out of titanium. In another example, the chamber may comprise an inert polymer coating. In another example, the chamber is made of glass. The chamber may be connected to exhaust ports 807, which may in turn be connected to chamber 808. Chamber 808 may comprise a bubbler. Chamber 808 may comprise a condenser apparatus (e.g., a cold head, a cold finer, a cold coil, etc.). Chamber 808 may be configured to prevent a flow of the one or more perovskite precursors out of the chamber 806 and into downstream environments. For example, a cold head can condense iodine gas to prevent it from being vented into the atmosphere.

FIG. 9 schematically illustrates a shower head design for a spray-on nozzle. Gas can flow through inlet 901 into deposition chamber 903 through nozzle 902. Nozzle 902 may comprise a plurality of holes 904. The plurality of holes may be at least about 2, 5, 10, 25, 50, 75, 100, 150, 200, 250, 500, 750, 1,000, or more holes. The plurality of holes may be at most about 1,000, 750, 500, 250, 200, 150, 100, 75, 50, 25, 10, 5, 3, or fewer holes. The plurality of holes may be configured to evenly distribute the gas from inlet 901 onto a substrate 905 within the chamber 903. The substrate may be a substrate as described elsewhere herein. The substrate may be placed on a heater 906. The heater may be configured to anneal the substrate. For example, the heater can anneal the substrate to permit a reaction of the perovskite precursors to form the perovskite layer. The chamber 903 may comprise one or more exhaust ports 907. The exhaust ports may be configured to remove excess gasses from the atmosphere of the chamber (e.g., excess reactants, oxygen, water, etc.). The chamber may comprise a light source 908 directed at a photodetector 909. The light source may comprise a laser (e.g., a green laser), an incoherent light source (e.g., a light emitting diode, etc.), or the like, or any combination thereof. The photodetector may comprise a zero-dimensional (0D) detector (e.g., a photodiode), a one-dimensional (1D) detector (e.g., a strip detector), a two-dimensional (2D) detector (e.g., an array detector), a film detector (e.g., a detector using silver halide crystals on a film), a phosphor plate detector (e.g., a plate of downshifting or down-converting phosphor), a semiconductor detector (e.g., a semiconductor charge coupled device (CCD), a complementary metal oxide semiconductor (CMOS) device), or the like, or any combination thereof.

The following examples are illustrative of certain systems and methods described herein and are not intended to be limiting.

### Example 1—Preparation of a Perovskite Photovoltaic Cell

An incoming glass substrate can be coated with indium tin oxide followed by nickel (II) oxide in a pair of physical vapor deposition processes to generate a substrate comprising a transparent conductive layer and a hole transport layer. The nickel oxide can then be laser scribed to generate templates of individual photovoltaic cells.

Subsequently, lead (II) iodide in a solution of dimethylformamide and dimethyl sulfoxide can be applied to the hole transport layer via an ultrasonic spray process. To the lead (II) iodide, methylammonium iodide in a solution of dimethylformamide and dimethyl sulfoxide can be applied via an ultrasonic spray process. The lead (II) iodide and the methylammonium iodide can be annealed to permit reaction of the two perovskite precursors and evaporation of the solvents, thus forming a methylammonium lead iodide perovskite layer. To the newly formed perovskite layer, a phenyl-C61-butyric acid methyl ester (PCBM) hole transport layer can be applied in a solution of dimethylformamide and dimethyl sulfoxide by an ultrasonic spray process. The hole transport layer can then be laser scribed along the same pattern as the nickel oxide.

Subsequently, a second transparent conducting layer of indium tin oxide can be applied via physical vapor deposition, followed by application of silver electrodes by a similar physical vapor deposition process. The electrodes can be cut via laser scribe to form the electrode assembly, and the individual photovoltaic cells can be isolated from one another by laser scribe.

Subsequently, the as formed photovoltaic cells can be investigated via various metrology techniques such as, for example, scanning electron microscopy (SEM), optical absorption/transmission, x-ray diffraction, atomic force microscopy, ellipsometry, electroluminescence spectroscopy, photoluminescence spectroscopy, time resolved optical spectroscopy, or the like, or any combination thereof.

After application of the second transparent conducting layer, an encapsulant can be applied to the back of the photovoltaic cell. The encapsulant can be applied prior to the isolation of the photovoltaic cells by laser scribe. A first encapsulant, such as a thermal polyolefin, can be applied across the back of the photovoltaic cell while a second encapsulant, such as butyl rubber, can be applied to the edges of the photovoltaic cell. The back encapsulant can be optically transparent, while the side encapsulant can be optically transparent or opaque. For example, a higher quality (e.g., lower moisture and gas permeability) encapsulant can be placed on the sides of the photovoltaic cell even though it is not optically transparent because the side of the cell does not absorb light, while the encapsulant for the back of the cell can be transparent to allow light to pass through to a bottom junction.

### Example 2—Inline Generation of Perovskite Photovoltaics

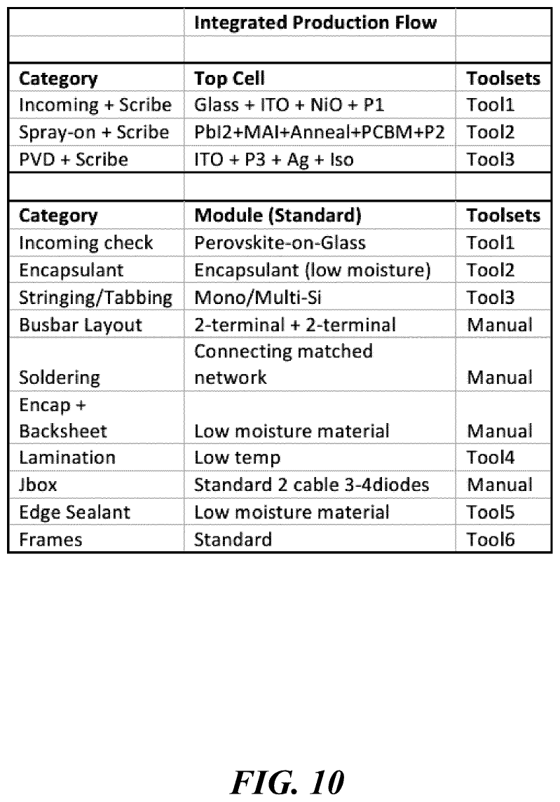

Each operation of the production of the perovskite photovoltaic cell may be integrated into a single instrument and/or location. For example, a substrate can be placed in a single instrument that performs all of the operations of process 300. The perovskite photovoltaic cell can be integrated with a second photovoltaic cell (e.g., a silicon photovoltaic cell) in the same instrument the perovskite cell was generated in. FIG. 10 is an example of an integrated production flow for a perovskite/silicon photovoltaic module. In this example, each operation can be performed in a same production line.

A large area (e.g., 1 meter×2 meter) glass substrate can be loaded onto a conveyor belt system configured to guide the glass substrate into an enclosure. The enclosure can comprise a controlled atmosphere (e.g., low moisture, oxygen content, temperature control, etc.). The enclosure can comprise a plurality of ultrasonic spray-on nozzles configured to spray a lead halide solution onto the glass substrate. Subsequent to the application of the lead halide solution, a different set of nozzles in the enclosure can apply a methylammonium halide/butyl halide solution to the lead halide. The conveyor belt can be configured to move the substrate from the lead halide application nozzles to the methylammonium halide/butyl halide solution application nozzles in a set time to permit formation of lead halide crystals that the methylammonium halide/butyl halide can integrate into to form a perovskite layer. After application of the methylammonium halide/butyl halide solution, the substrate can move into an annealing oven. Within the annealing oven, the substrate can be heated to form a perovskite layer with predetermined characteristics (e.g., grain size, thickness, elemental distribution, etc.). The annealing oven may be inline with the conveyor belt (e.g., the conveyor belt moves through the oven to perform the annealing). The annealing oven may be a batch annealing oven (e.g., multiple substrates can be loaded into the oven to be annealed at the same time). The type of annealing oven may be determined by the cycle time of the oven as compared to the anneal duration.

After formation of the perovskite layer, the substrate can pass through another set of ultrasonic spray-on nozzles for application of the electron transport layer to the perovskite layer. A second transparent conductive layer can then be applied via physical vapor deposition to the electron transport layer, electrodes can be applied via physical vapor deposition, and the individual photovoltaic cells can be isolated via laser scribe. The entire inline process can take place on a single conveyor belt.

### Example 3—Use of PDMS as an Encapsulant

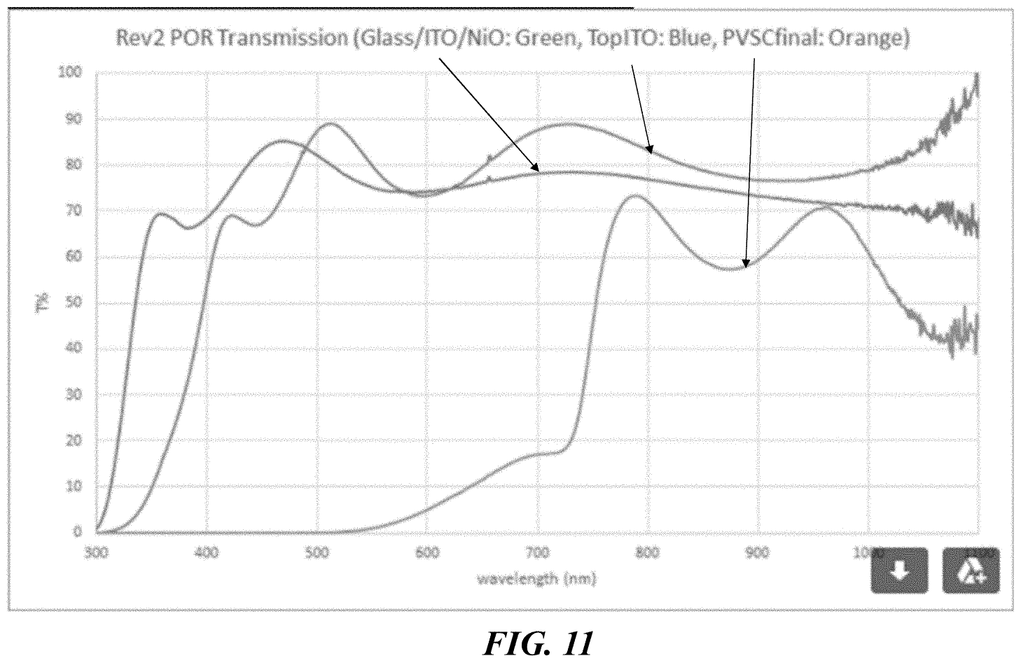

PDMS may be used as an encapsulant in a tandem, 4-terminal, silicon-perovskite solar module (i.e., the solar module 100 of FIG. 1). The PDMS encapsulant was placed between the perovskite solar cell and the silicon solar cell during the lamination of the perovskite to the silicon solar cell. FIG. 11 shows the transmission of various wavelengths of light through the perovskite solar cell when the PDMS encapsulant is not used. The average transmission percentage through the top TCO layer is 72.24. The average weighted transmission percentage is 74.67%. The average weighted transmission percentage is weighted according to the power delivered by each wavelength of light. The average transmission percentage through the top glass layer, the top TCO layer, and the HTL is 72.20%. The average weighted transmission percentage is 72.68%. The average transmission percentage through the perovskite solar cell is 29.20%. The average weighted transmission percentage is 24.34%. When a PDMS encapsulant is used, the transmission percentage to the silicon solar cell improves to 40.44%, with a weighted average of 33.48%.

Table 1 below shows the improvements in voltage and current characteristics when the PDMS encapsulant is used. In particular, short circuit current density improves from 13.93 milliamps per square centimeter (“mA/cm²”) with an airgap between the perovskite solar cell and the silicon solar cell to 22.72 mA/cm² when the air gap is filled with a spun-on PDMS. Within Table 1, “EFF” refers to efficiency, “FF” refers to fill factor of the current/voltage graph, the “aperture” refers to a test of the photovoltaic cell in which a portion of the cell is illuminated through an aperture that blocks the rest of the cell, while “cell itself” refers to a measurement over the entire cell without an aperture.

TABLE 1

| | | | Spun-on |
|---|---|---|---|
| | Cell | Airgap, | PDMS, |
| | itself | aperature | aperature |
| EFF (%) | 20.12 | 5.75 | 8.54 |
| FF (%) | 76 | 71.9 | 70.1 |
| Open circuit voltage (Voc) | 649.4 | 573.8 | 535.7 |
| (millivolts) | | | |
| Short circuit current density (Jsc) | 40.74 | 13.93 | 22.72 |
| (milliamps/square centimeter) | | | |
| Maximum voltage (Vmax) | 528.4 | 460.5 | 421.7 |
| (millivolts) | | | |
| Maximum current density (Jmax) | 38.07 | 12.48 | 20.25 |
| (milliamps/square centimeter) | | | |
| Short circuit current (Isc) (amps) | 0.102 | 0.0163 | 0.005772 |
| Short circuit resistance (Rsc) | 385.66 | 327.47 | 97473 |
| (Ohms) | | | |
| Open circuit resistance (Roc) | 0.417 | 2.8526 | 4.9478 |
| (Ohms) | | | |
| Area (square centimeters) | 2.5 | 1.17 | 0.254 |

### Example 4—Use of PDMS on the Top Glass Sheet

PDMS may be applied to the top glass sheet of a tandem, 4-terminal, silicon-perovskite solar module (i.e., the solar module 100 of FIG. 1). Table 2 shows the resulting uptick in short circuit current density when such various types of PDMS are used. The improvements are the result of better light trapping and refractive index matching as light travels to the perovskite solar cell from the air, through the PDMS, and to the glass.

TABLE 2

| | | 1:10 | textured 1:50 | textured |
|---|---|---|---|---|
| | bare | alumina_PDMS | alumina_PDMS | PDMS |
| EFF | 15.39 | 16.35 | 16.32 | 16.83 |
| FF | 74.6 | 75.3 | 74.9 | 74.8 |
| Voc | 1105.1 | 1105.5 | 1117.7 | 1125 |
| Jsc | 18.67 | 19.63 | 19.49 | 20.01 |
| Vmax | 900 | 900 | 920 | 920 |
| Jmax | 17.1 | 18.16 | 17.74 | 18.3 |
| Isc | 0.004741 | 0.004986 | 0.004951 | 0.005083 |
| Rsc | 12125 | 25615 | 15660 | 22587 |
| Roc | 22.993 | 20.78 | 22.156 | 23.072 |

| | |
|---|---|
| Area | 0.254 |

### Computer Systems

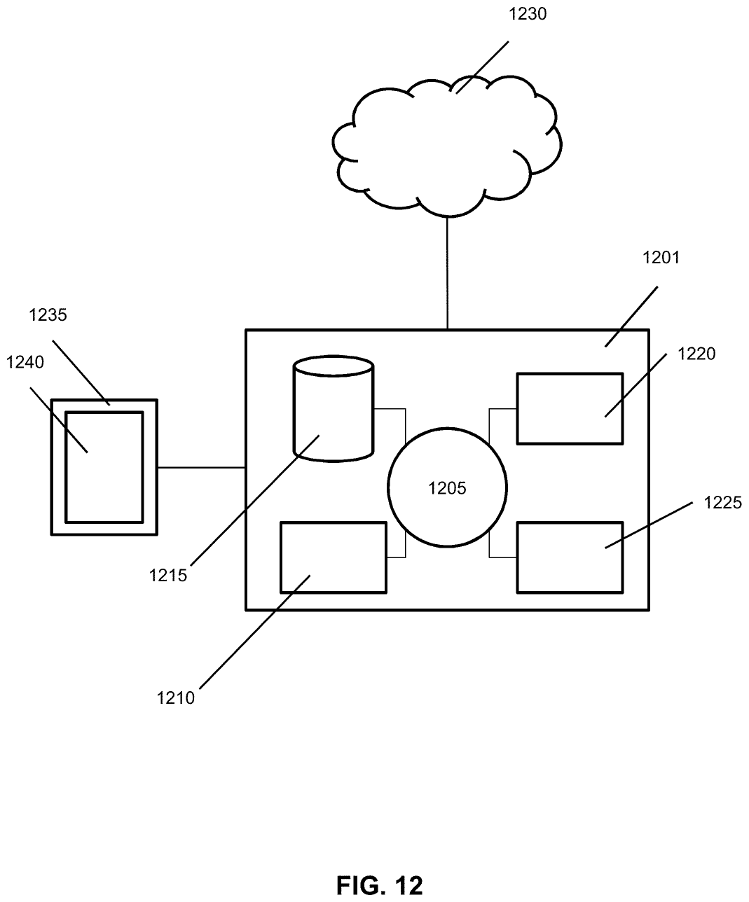

The present disclosure provides computer systems that are programmed to implement methods of the disclosure. FIG. 12 shows a computer system 1201 that is programmed or otherwise configured to direct the fabrication and manufacturing processes described herein (e.g., physical vapor deposition, ultrasonic spray-on, etc.) or control power electronics connected to the solar modules described herein.

The computer system 1201 includes a central processing unit (CPU, also “processor” and “computer processor” herein) 1205, which can be a single core or multi core processor, or a plurality of processors for parallel processing. The computer system 1201 also includes memory or memory location 1210 (e.g., random-access memory, read-only memory, flash memory), electronic storage unit 1215 (e.g., hard disk), communication interface 1220 (e.g., network adapter) for communicating with one or more other systems, and peripheral devices 1225, such as cache, other memory, data storage and/or electronic display adapters. The memory 1210, storage unit 1215, interface 1220 and peripheral devices 1225 are in communication with the CPU 1205 through a communication bus (solid lines), such as a motherboard. The storage unit 1215 can be a data storage unit (or data repository) for storing data. The computer system 1201 can be operatively coupled to a computer network (“network”) 1230 with the aid of the communication interface 1220. The network 1230 can be the Internet, an internet and/or extranet, or an intranet and/or extranet that is in communication with the Internet. The network 1230 in some cases is a telecommunication and/or data network. The network 1230 can include one or more computer servers, which can enable distributed computing, such as cloud computing. The network 1230, in some cases with the aid of the computer system 1201, can implement a peer-to-peer network, which may enable devices coupled to the computer system 1201 to behave as a client or a server.

The CPU 1205 can execute a sequence of machine-readable instructions, which can be embodied in a program or software. The instructions may be stored in a memory location, such as the memory 1210. The instructions can be directed to the CPU 1205, which can subsequently program or otherwise configure the CPU 1205 to implement methods of the present disclosure. Examples of operations performed by the CPU 1205 can include fetch, decode, execute, and writeback.

The CPU 1205 can be part of a circuit, such as an integrated circuit. One or more other components of the system 1201 can be included in the circuit. In some cases, the circuit is an application specific integrated circuit (ASIC).

The storage unit 1215 can store files, such as drivers, libraries and saved programs. The storage unit 1215 can store user data, e.g., user preferences and user programs. The computer system 1201 in some cases can include one or more additional data storage units that are external to the computer system 1201, such as located on a remote server that is in communication with the computer system 1201 through an intranet or the Internet.

The computer system 1201 can communicate with one or more remote computer systems through the network 1230. For instance, the computer system 1201 can communicate with a remote computer system of a user. Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. The user can access the computer system 1201 via the network 1230.

Methods as described herein can be implemented by way of machine (e.g., computer processor) executable code stored on an electronic storage location of the computer system 1201, such as, for example, on the memory 1210 or electronic storage unit 1215. The machine executable or machine-readable code can be provided in the form of software. During use, the code can be executed by the processor 1205. In some cases, the code can be retrieved from the storage unit 1215 and stored on the memory 1210 for ready access by the processor 1205. In some situations, the electronic storage unit 1215 can be precluded, and machine-executable instructions are stored on memory 1210.

The code can be pre-compiled and configured for use with a machine having a processer adapted to execute the code or can be compiled during runtime. The code can be supplied in a programming language that can be selected to enable the code to execute in a pre-compiled or as-compiled fashion.

Aspects of the systems and methods provided herein, such as the computer system 1201, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The computer system 1201 can include or be in communication with an electronic display 1235 that comprises a user interface (UI) 1240 for providing, for example, control over a fabrication process parameters. Examples of UI's include, without limitation, a graphical user interface (GUI) and web-based user interface.

Methods and systems of the present disclosure can be implemented by way of one or more algorithms. An algorithm can be implemented by way of software upon execution by the central processing unit 1205.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

1. A device, comprising:
a plurality of silicon solar cell assemblies, each silicon solar cell assembly having a first band gap; and
a perovskite solar cell assembly covering and in contact with each of the plurality of silicon solar cell assemblies, wherein the perovskite solar cell assembly comprises:
(i) a top glass sheet, wherein the top glass sheet comprises a top surface and a bottom surface, wherein the top glass covers the plurality of silicon solar cell assemblies; and
(ii) a perovskite solar cell having a second band gap, wherein the perovskite solar cell is deposited on the bottom surface of the top glass, wherein the perovskite solar cell is adjacent to each of the plurality of silicon solar cell assemblies.

2. The device of claim 1, wherein the plurality of silicon solar cell assemblies are electrically isolated from the perovskite solar cell.

3. The device of claim 2, wherein the plurality of silicon solar cell assemblies comprise two terminals and the perovskite solar cell comprises two terminals.

4. The device of claim 1, wherein the perovskite solar cell comprises a photoactive perovskite layer, wherein the photoactive perovskite layer comprises CH₃NH₃PbX₃ or H₂NCHNH₂PbX₃.

5. The device of claim 4, wherein X comprises iodide, bromide, chloride, or any combination thereof.

6. The device of claim 1, wherein the perovskite solar cell comprises a first transparent conductive oxide (TCO) layer and a second TCO layer.

7. The device of claim 6, wherein the first TCO layer and the second TCO layer are terminals of the perovskite solar cell.

8. The device of claim 7, wherein the first TCO layer and the second TCO layer comprise indium oxide.

9. The device of claim 1, wherein the perovskite solar cell comprises an electron transport layer (ETL) comprising phenyl-C61-butyric acid methyl ester.

10. The device of claim 1, wherein the perovskite solar cell comprises a hole transport layer (HTL) comprising nickel oxide.

11. The device of claim 1, further comprising a plurality of perovskite solar cells including the perovskite solar cell, wherein the plurality of perovskite solar cells is laser scribed in the top glass sheet so as to voltage-match or current-match the plurality of perovskite solar cells to the plurality of silicon solar cell assemblies.

12. The device of claim 1, wherein the top glass sheet has a surface area that substantially corresponds to a surface area of a 60- or 72-cell solar panel.

13. The device of claim 1, wherein the top surface of the top glass sheet comprises an anti-reflective coating.

14. The device of claim 1, wherein the top surface of the top glass sheet comprises polydimethylsiloxane (PDMS).

15. The device of claim 14, wherein the PDMS comprises 1:10 alumina PDMS, textured 1:50 alumina PDMS, or textured PDMS.

16. The device of claim 1, wherein the bottom surface of the top glass sheet has a textured surface.

17. The device of claim 1, further comprising an encapsulant disposed between the plurality of silicon solar cell assemblies and the perovskite solar cell.

18. The device of claim 17, wherein the encapsulant is selected from the group consisting of ethylene-vinyl-acetate (“EVA”), thermal plastic polyolefin (“TPO”), PDMS, silicone, and paraffin.

19. The device of claim 1, wherein the plurality of silicon solar cell assemblies and the perovskite solar cell are connected electrically in parallel.

20. The device of claim 1, wherein the plurality of silicon solar cell assemblies and the perovskite solar cell are connected electrically in series.

21. The device of claim 1, wherein the second bandgap is between about 1.5 and 1.9 electron volts (eV).

22. The device of claim 1, wherein silicon solar cells of the plurality of silicon solar cell assemblies are individually selected from the group consisting of monocrystalline solar cells, polycrystalline solar cells, passivated emitter rear contact (PERC) solar cells, interdigitated back contact cells (IBC), and heterojunction with intrinsic thin layer (HIT) solar cells.

23. A method for manufacturing a solar module comprising:
(a) providing a silicon solar cell having a first band gap;
(b) forming a perovskite solar cell having a second band gap in a bottom surface of a glass sheet; and
(c) affixing the glass sheet to the silicon solar cell to form the solar module such that the bottom surface of the glass sheet is adjacent to the silicon solar cell.
